(19) United States
(12) Patent Application Publication
(10) Pub. No.: US 2021/0367091 A1
(43) Pub. Date: Nov. 25, 2021

(54) HARVESTING OF ENERGY FROM DIVERSE WAVELENGTHS

(71) Applicant: Technion Research & Development Foundation Limited, Haifa (IL)

(72) Inventors: Carmel ROTSCHILD, Ganei-Tikva (IL); Assaf MANOR, Haifa (IL); Shimry HAVIV, Kiryat Tivon (IL)

(73) Assignee: Technion Research & Development Foundation Limited, Haifa (IL)

(21) Appl. No.: 16/765,881

(22) PCT Filed: Nov. 21, 2018
(86) PCT No.: PCT/IL2018/051265

§ 371 Date: May 21, 2020

Related U.S. Application Data
(60) Provisional application No. 62/589,017, filed on Nov. 21, 2017.
(60) Provisional application No. 62/622,997, filed on Jan. 29, 2018.
(60) Provisional application No. 62/735,937, filed on Sep. 25, 2018.

(51) Int. Cl. H01L 31/055; H01L 31/054; F24S 20/20; F24S 70/10; F24S 70/60; F03G 6/06

(52) U.S. Cl. CPC H01L 31/055; H01L 31/0547; F03G 6/065; F24S 70/10; F24S 70/60; F24S 20/20

(57) ABSTRACT

A system for energy conversion including photoluminescent (PL) material for absorbing solar radiation and emitting PL radiation, a solar concentrator for concentrating solar radiation on the PL material, photovoltaic (PV) material configured to absorb the PL radiation, and a chamber for containing the PL material and Heat Transfer Fluid (HTF), and further including the system configured to pipe the HTF from the chamber to a system for conversion of HTF heat to energy. Related apparatus and methods are also described.

### RELATED APPLICATIONS

This application is related to and claims priority from U.S. Provisional Patent Application No. 62/735,937 filed on Sep. 25, 2018, from U.S. Provisional Patent Application No. 62/622,997 filed on Jan. 29, 2018 and from U.S. Provisional Patent Application No. 62/589,017 filed on Nov. 21, 2017. The contents of all of the above applications are all incorporated by reference as if fully set forth herein in their entirety.

### FIELD AND BACKGROUND OF THE INVENTION

The present invention, in some embodiments thereof, relates to methods and devices for producing electricity from absorbed radiation and/or heat and, more particularly, but not exclusively, to using photo-luminescent (PL) material to absorb radiation and re-emit radiation onto one or more photovoltaic materials, and, more particularly, but not exclusively, to using PL material to absorb solar radiation, even at a point of solar radiation concentrated by heliostats to a top of a solar tower.

The disclosures of all references mentioned throughout the present specification, as well as the disclosures of all references mentioned in those references, are hereby incorporated herein by reference.

### SUMMARY OF THE INVENTION

The present invention, in some embodiments thereof, relates to methods and devices for producing electricity from absorbed radiation and/or heat and, more particularly, but not exclusively, to using photo-luminescent (PL) material to absorb radiation and re-emit radiation onto one or more photovoltaic materials, and, more particularly, but not exclusively, to using PL material to absorb solar radiation, even at a point of solar radiation concentrated by heliostats to a top of a solar tower. In some embodiments, the heat in the PL material is converted to electricity using a heat engine. In some embodiments, the heat in the PL material is converted to electricity using a heat engine and radiation from the PL material is converted to electricity using PV cells. In some embodiments, the heat in the PL material is converted to electricity using a heat engine and radiation from the PL material is converted to electricity using PV cells and solar radiation is converted to electricity using PV cells.

According to an aspect of some embodiments of the present invention there is provided a system for energy conversion including photoluminescent (PL) material for absorbing solar radiation and emitting PL radiation, a solar concentrator for concentrating solar radiation on the PL material, photovoltaic (PV) material configured to absorb the PL radiation, and a chamber for containing the PL material and Heat Transfer Fluid (HTF), and further including the system configured to pipe the HTF from the chamber to a system for conversion of HTF heat to energy.

According to some embodiments of the invention, the system is included in a solar energy harvesting system.

According to some embodiments of the invention, the system is located at a location of concentrated solar power at a concentration of more than 50 suns.

According to some embodiments of the invention, the system for conversion of HTF heat to energy includes a heat engine.

According to some embodiments of the invention, the chamber includes an optical cavity reflecting the PL radiation toward the PV material.

According to some embodiments of the invention, the chamber includes walls are transmissive at wavelengths corresponding to a bandgap of the PV material.

According to some embodiments of the invention, the PL material is configured to emit PL radiation including at least enough energy to be absorbed by the PV material and cause the PV material to generate electricity.

According to some embodiments of the invention, the system for conversion of HTF heat to energy includes a heat engine.

According to some embodiments of the invention, the heat of the HTF is used for splitting water.

According to some embodiments of the invention, the heat the heat of the HTF is used for generating syngas.

According to an aspect of some embodiments of the present invention there is provided a method for energy conversion including placing photoluminescent (PL) material in concentrated solar radiation, thereby causing the PL material to absorb solar radiation, to heat and to emit PL radiation, placing photovoltaic (PV) material in the PL radiation to produce electricity, heating Heat Transfer Fluid (HTF) by placing near the heated PL material, and piping the heated HTF to a system for conversion of HTF heat to energy.

According to some embodiments of the invention, the system for conversion of HTF heat to energy includes a system for converting to electricity.

According to some embodiments of the invention, the system for conversion of HTF heat to energy includes a system for converting to chemical energy.

According to some embodiments of the invention, the placing the PL material in concentrated solar radiation includes placing the PL material in a solar energy harvesting system.

According to some embodiments of the invention, the solar energy harvesting system is located at a location of concentrated solar power at a concentration of more than 50 suns.

According to some embodiments of the invention, the system for conversion of HTF heat to energy includes a turbine.

According to some embodiments of the invention, the PV material is included in PV solar cells.

According to an aspect of some embodiments of the present invention there is provided a system for producing electric energy including a photoluminescent (PL) material having a plurality of PL emission wavelength peaks, placed at a location of incoming radiation, a first photovoltaic (PV) cell including a first higher bandgap PV material to absorb radiation emitted by the PL material at a first PL emission wavelength peak, and

a second PV cell including a second lower bandgap PV material to absorb radiation emitted by the PL material at a second PL emission wavelength peak.

According to some embodiments of the invention, the incoming radiation includes solar radiation. According to some embodiments of the invention, the incoming radiation includes concentrated solar radiation.

According to some embodiments of the invention, further including insulation for maintaining heat of the PL material. According to some embodiments of the invention, the PL material is located in a thermally insulating cavity.

According to some embodiments of the invention, the PL material is located in a cavity which captures radiation at least at wavelengths emitted by the PL material.

According to some embodiments of the invention, the PV material is arranged along walls of the cavity which captures radiation.

According to some embodiments of the invention, the cavity which captures radiation is reflective at least at an edge of emission wavelengths emitted by the PL material.

According to some embodiments of the invention, the PL material is enclosed in a vacuum chamber.

According to some embodiments of the invention, further including a wavelength selective radiation scatterer included within the PL material.

According to some embodiments of the invention, the wavelength selective scatterer is selected from a group consisting of: Plasmonic nano-particles, Dielectric nano-particles, Mie scattering particles, and Rayleigh scattering particles.

According to some embodiments of the invention, the wavelength selective scatterer scatters radiation at a wavelength range matching a bandgap of the first higher bandgap PV material.

According to some embodiments of the invention, the PL material is at a top of a solar power tower.

According to some embodiments of the invention, the PL material is at a focus of concentrated solar power.

According to some embodiments of the invention, further including a solar concentrator to concentrate solar radiation onto the PL material.

According to some embodiments of the invention, the solar concentrator includes a plurality of heliostats.

According to some embodiments of the invention, further including a turbine for generating electricity from heat absorbed by the PL material.

According to some embodiments of the invention, further including a wavelength selective radiation scatterer included within the PL material. According to some embodiments of the invention, further including a wavelength selective radiation scatterer included in a surface of the PL material.

According to some embodiments of the invention, the wavelength selective radiation scatterer is designed to scatter radiation at a wavelength matching a bandgap of at least one of the first PV cell and the second PV cell.

According to some embodiments of the invention, the wavelength selective radiation scatterer is designed to scatter radiation at a wavelength matching a bandgap of a larger one of the bandgap of the first PV cell and the bandgap of the second PV cell.

According to some embodiments of the invention, the wavelength selective radiation scatterer is placed at a location which scatters light toward the first PV cell.

According to some embodiments of the invention, the wavelength selective radiation scatterer is placed at a location which scatters light toward the second PV cell.

According to an aspect of some embodiments of the present invention there is provided a method for producing electric energy including heating a photoluminescent (PL) material, exposing the PL material to incident radiation, thereby causing the PL material to emit radiation at least two PL emission wavelength peaks, and using at least one photovoltaic (PV) cell having at least two PV absorption band-gaps to absorb radiation emitted by the PL material using at least two of the PL emission wavelength peaks and produce electric energy.

According to an aspect of some embodiments of the present invention there is provided a method for producing electric energy including heating a photoluminescent (PL) material, exposing the PL material to incident radiation, thereby causing the PL material to emit radiation at at least one PL emission wavelength peak, and using at least one photovoltaic (PV) cell having at least one PV absorption band-gaps to absorb radiation emitted by the PL material using at least one of the PL emission wavelength peaks and produce electric energy.

According to some embodiments of the invention, the heating is by absorption of the incident radiation.

According to some embodiments of the invention, further including insulating the PL material to maintain heat. According to some embodiments of the invention, further including insulating the PL material from the PV cell.

According to some embodiments of the invention, the incident radiation is solar radiation.

According to some embodiments of the invention, the PL material is at a top of a solar power tower.

According to some embodiments of the invention, further including concentrating solar radiation onto the PL material.

According to some embodiments of the invention, further including concentrating solar radiation onto the PL material using a plurality of heliostats.

According to some embodiments of the invention, the heating the PL material includes heating to a temperature above 50 degrees Celsius. According to some embodiments of the invention, the heating the PL material includes heating to a temperature above 98 degrees Celsius. According to some embodiments of the invention, the heating the PL material includes heating to a temperature above 100 degrees Celsius. According to some embodiments of the invention, the heating the PL material includes heating to a temperature above 300 degrees Celsius. According to some embodiments of the invention, the heating the PL material includes heating to a temperature above 500 degrees Celsius. According to some embodiments of the invention, the heating the PL material includes heating to a temperature in a range between 100 degrees Celsius and 1000 degrees Celsius. According to some embodiments of the invention, the heating the PL material includes heating to a temperature in a range between 99 degrees Celsius and 1500 degrees Celsius. According to some embodiments of the invention, the heating the PL material includes heating to a temperature of 1000 degrees Celsius. According to some embodiments of the invention, the heating the PL material includes heating to a temperature of 1500 degrees Celsius.

According to some embodiments of the invention, further including using a turbine to generate electricity from heat absorbed by the PL material.

According to some embodiments of the invention, further including using a wavelength selective radiation scatterer included within the PL material to scatter radiation toward the PV cell.

According to some embodiments of the invention, further including using a wavelength selective radiation scatterer included in a surface of the PL material to scatter radiation toward the PV cell.

According to an aspect of some embodiments of the present invention there is provided apparatus for producing electric energy including a photoluminescent (PL) material having a plurality of PL emission wavelength peaks, at least one photovoltaic (PV) cell having at least a first higher bandgap PV material and a second lower bandgap PV material to absorb radiation emitted by the PL material using one of the PL emission wavelength peaks and to absorb radiation not emitted by the PL material and produce electric energy.

According to an aspect of some embodiments of the present invention there is provided apparatus for producing electric energy including a photoluminescent (PL) material having a plurality of PL emission wavelength peaks, at least one photovoltaic (PV) cell having at least a first higher bandgap PV material and a second lower bandgap PV material to absorb radiation emitted by the PL material using at least two of the PL emission wavelength peaks and produce electric energy.

According to some embodiments of the invention, the second lower bandgap PV material absorbs radiation at a wavelength matching a wavelength of an emission band edge of the PL material and the first higher bandgap PV material absorbs radiation at a wavelength shorter than the emission band edge of the PL material.

According to some embodiments of the invention, further including a selective filter in front of the second lower bandgap PV material to reflect radiation at a spectral range that matches wavelengths of the higher bandgap PV material thereby directing radiation onto the first higher bandgap PV material.

According to some embodiments of the invention, further including the PL material located at a location of focused radiation.

According to some embodiments of the invention, the at least one photovoltaic (PV) cell includes a plurality of PV cells.

According to some embodiments of the invention, the plurality of PV cells includes at least a first PV cell and a second PV cell in a tandem configuration.

According to some embodiments of the invention, the at least one photovoltaic (PV) cell includes a plurality of PV cells, at least a first one of the plurality of PV cells using at least a first one of the PL emission wavelength peaks to produce electric energy and at least a second one of the plurality of PV cells using at least a second one of the PL emission wavelength peaks to produce electric energy.

According to some embodiments of the invention, the low bandgap and high bandgap PV material are selected from a group consisting of: Si, GaAs, c-Si, InP, InGaP, GaInNAs, mc-Si, CdTe, AlGaAs, GaSb, Ge, a-Si, Cu2S, CIGS, GaP, GaN, PbO, Perovskites.

According to some embodiments of the invention, the first higher bandgap PV material is selected from a group consisting of: GaAs, GaInP, InP, CdTe, a-Si, AlGaAs, GaInAs, GaInAsP, AlGaInP, InGaAs, InGaP, CdS GaP, GaN, PbO, CdSe, PbI2 Cu2O, ZnTe, MAPI, ZnO, SiC, GaAsP.

According to some embodiments of the invention, the second lower bandgap PV material is selected from a group consisting of: c-Si, mc-Si, Si, GaSb, Ge, CIGS, GaInS, GaInAsP, GaInNAs.

According to some embodiments of the invention, the PL material includes Nd+3, the first higher bandgap PV material includes Silicon, and the second lower bandgap PV material includes Gallium Arsenide.

According to some embodiments of the invention, further including the PL material located in a thermal insulation chamber.

According to some embodiments of the invention, the PL material is located in a cavity designed to capture the PL emission.

According to some embodiments of the invention, the first higher bandgap PV material and the second lower bandgap PV material are located in the cavity designed to capture the PL emission.

According to some embodiments of the invention, walls of the cavity are reflective at a wavelength of the PL material photoluminescence wavelength.

According to some embodiments of the invention, further including a wavelength-selective reflective filter located at an entrance of the cavity, wherein the selective reflectivity matches a wavelength of a low energy edge of an emission band of the PL material, thereby capturing the emission of the PL material.

According to some embodiments of the invention, further including a wavelength-selective reflective filter located at an entrance of the cavity, wherein the selective reflectivity matches a wavelength of peak emission of the PL material.

According to some embodiments of the invention, the high reflectivity of the entrance filter is at a spectral range between Eg(PL)−0.1 eV and Eg(PL)+0.1 eV, where Eg(PL) is a low energy edge of an emission band of the PL material.

According to some embodiments of the invention, the first higher bandgap PV material and the second lower bandgap PV material are also placed within the cavity.

According to some embodiments of the invention, a shape of the cavity includes a shape selected from a group consisting of spherical, hemispherical, paraboloid, parabolic and cylindrical.

According to some embodiments of the invention, the cavity includes reflective walls. According to some embodiments of the invention, the reflective walls are designed to reflect wavelengths at the PL emission wavelength peaks and reflect less at other wavelengths.

According to some embodiments of the invention, the reflective walls include thin-film coatings designed to reflect wavelengths at the PL emission wavelength peaks and reflect less at other wavelengths. According to some embodiments of the invention, the reflective walls are designed to reflect wavelengths corresponding to at least one of the first higher bandgap PV material and the second lower bandgap PV material. According to some embodiments of the invention, the reflective walls are designed to reflect a plurality of wavelengths corresponding to a plurality of PV material bandgaps.

According to some embodiments of the invention, the PL material includes a dopant selected from a group consisting of: quantum dots, nano-particles, gold nano-particles, TiN nano-particles, rare earths, Ytterbium, Neodymium, Nd+3, Europium, Erbium, direct band-gap semiconductors, InGa, CdTe, transition metals, Chromium, Cerium and Platinum.

According to some embodiments of the invention, further including a turbine for generating electricity from heat absorbed by the PL material.

According to some embodiments of the invention, further including a wavelength selective radiation scatterer included with the PL material. According to some embodiments of the invention, further including a wavelength selective radiation scatterer included in a surface of the PL material.

According to some embodiments of the invention, the wavelength selective radiation scatterer is designed to scatter radiation at a wavelength matching a bandgap of at least one of the first PV cell and the second PV cell.

According to some embodiments of the invention, the wavelength selective radiation scatterer is designed to scatter radiation at a wavelength matching a bandgap of a larger one of the bandgap of the first PV cell and the bandgap of the second PV cell.

According to some embodiments of the invention, the wavelength selective radiation scatterer is placed at a location which scatters light toward the first PV cell. According to some embodiments of the invention, the wavelength selective radiation scatterer is placed at a location which scatters light toward the second PV cell.

According to an aspect of some embodiments of the present invention there is provided a method for producing electric energy including heating a photoluminescent (PL) material, exposing the PL material to incident radiation, thereby causing the PL material to emit radiation at a first wavelength peak, using at least one photovoltaic (PV) cell having at least two PV materials having at least two absorption band-gaps to absorb the incident radiation and the radiation emitted by the PL material and produce electric energy.

According to some embodiments of the invention, the heating is performed by exposure to the incident radiation.

According to some embodiments of the invention, further including using a turbine to generate electricity from heat absorbed by the PL material.

According to some embodiments of the invention, further including using a wavelength selective radiation scatterer included within the PL material to scatter radiation toward the PV cell.

According to some embodiments of the invention, further including using a wavelength selective radiation scatterer included in a surface of the PL material to scatter radiation toward the PV cell.

According to an aspect of some embodiments of the present invention there is provided a method for energy conversion including providing a device including a photoluminescent (PL) material for absorbing solar radiation and emitting PL radiation, a first solar cell with a first bandgap to absorb a first spectral range of the PL radiation, a second solar cell with a second bandgap to absorb a second spectral range of the PL radiation, a cavity for containing the PL material, the first solar cell and the second solar cell and confining the PL radiation, heating the PL material by thermalization of the solar radiation, using the PL material for absorbing the solar radiation, generating electricity from the absorbed solar radiation.

According to some embodiments of the invention, the PL material includes a dopant selected from a group consisting of: quantum dots, nano-particles, gold nano-particles, rare earths, Ytterbium, Neodymium, Europium, Erbium, direct band-gap semiconductors, InGa, and CdTe.

According to some embodiments of the invention, the PL material is placed inside a thermal insulation chamber.

According to some embodiments of the invention, the first solar cell and the second solar cell include PV material selected from a group consisting of: Si, GaAs, c-Si, InP, InGaP, GaInNAs, mc-Si, CdTe, AlGaAs, GaSb, Ge, a-Si, perovskite, and a perovskite structured compound.

According to some embodiments of the invention, the first bandgap matches a band-edge emission of the PL material and the second bandgap is greater than the band-edge of the PL material.

According to some embodiments of the invention, the first solar and second solar cell are placed in a tandem configuration.

According to some embodiments of the invention, the device further includes a selective filter in front of the second solar cell to reflect light at a spectral range that matches the second bandgap thereby directing reflected light onto the second solar cell.

According to some embodiments of the invention, the device further includes a wavelength selective reflective entrance filter at an entrance of the cavity and the reflectivity is at a wavelength matching a band edge emission of the PL material.

According to some embodiments of the invention, the reflectivity of the entrance filter is high at a spectral range between Eg(PL)−0.1 eV and Eg(PL)+0.1 eV, where Eg(PL) is the band-edge emission energy of the PL material.

According to some embodiments of the invention, the PL material includes Nd+3, the first solar cell includes a Si photovoltaic (PV) material, the second solar cell includes a GaAs PV material.

According to an aspect of some embodiments of the present invention there is provided a system for energy conversion including a photoluminescent (PL) material for absorbing solar radiation and emitting PL radiation, a first solar cell with a first bandgap to absorb a first spectral range of the PL radiation, a second solar cell with a second bandgap to absorb a second spectral range of the PL radiation, and a thermally insulated cavity for containing the PL material, the first solar cell and the second solar cell and confining radiation emitted by the PL material, wherein the PL material is placed at a focus of concentrated solar radiation.

According to some embodiments of the invention, walls of the cavity walls include high reflectivity mirrors which are highly reflective at a wavelength range of the radiation emitted by the PL material.

According to some embodiments of the invention, a shape of the cavity is a shape selected from a group consisting of: spherical, hemispherical, a two-dimensional paraboloid, a parabola, and cylindrical.

According to an aspect of some embodiments of the present invention there is provided a system for converting waste heat to electricity including a laser for producing pumping radiation, a photoluminescent (PL) material for absorbing the pumping radiation and waste heat and emitting PL radiation at a wavelength shorter than the pumping radiation, and a photovoltaic (PV) material with a bandgap to absorb the PL radiation and produce electricity.

According to some embodiments of the invention, the photovoltaic (PV) material includes a first PV material with a first bandgap to absorb a first spectral range of the PL radiation, a second PV material with a second bandgap to absorb a second spectral range of the PL radiation.

According to some embodiments of the invention, further including a beam splitter configured to separate optical paths of the first spectral range of the PL radiation and the second spectral range of the PL radiation.

According to some embodiments of the invention, further including a beam splitter configured to direct the first spectral range of the PL radiation to the first PV material and the second spectral range of the PL radiation to the second PV material.

According to some embodiments of the invention, a surface area of the PV material for absorbing radiation is larger by a factor of N than a surface area for emission from the PL material, where the factor N is at least 10.

According to some embodiments of the invention, the solar cells are designed for a solar concentration of at least 50 suns.

According to some embodiments of the invention, the solar cells are designed for a solar concentration of at least 100 suns.

According to some embodiments of the invention, further including a material with an absorption spectrum between 1 micron and 1.5 microns for absorbing radiation from the sun, and transferring heat to a Heat Transfer Fluid (HTF).

According to some embodiments of the invention, the material with an absorption spectrum between 1 micron and 1.5 microns includes a layer of Indium Tin Oxide (ITO).

According to some embodiments of the invention, the PL material has a refractive index lower than 1.5.

According to some embodiments of the invention, the PL material is shaped in a prism shape thereby reducing wave-guiding of radiation emitted from the PL material.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWING(S)

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a graph showing power spectra lines of Nd⁺³ photoluminescence at various temperatures according to an example embodiments of the invention;

FIG. 2A is a simplified illustration of a system for photovoltaic harvesting of energy according to an example embodiment of the invention;

FIG. 2B is a simplified illustration of a system for photovoltaic harvesting of energy according to an example embodiment of the invention;

FIG. 2C is a simplified illustration of a system for photovoltaic harvesting of energy according to an example embodiment of the invention;

FIGS. 3A and 3B are simplified illustrations of a system for photovoltaic harvesting of energy according to an example embodiment of the invention;

FIG. 4 is a simplified illustration of a system for photovoltaic harvesting of energy according to an example embodiment of the invention;

FIGS. 5A, 5B and 5C are simplified illustration of systems for photovoltaic harvesting of energy according to some example embodiments of the invention;

FIG. 6 is a simplified illustration of a system for photovoltaic harvesting of energy, locating different scatterers at different locations, according to an example embodiment of the invention;

FIG. 7 is a simplified illustration of a system for photovoltaic harvesting of energy and using heat transfer fluid to harvest additional energy according to an example embodiment of the invention;

FIG. 8, which is a simplified illustration of a system for photovoltaic harvesting of energy and using liquid cooling to harvest additional energy according to an example embodiment of the invention.

FIGS. 9A and 9B are simplified illustrations of a system for photovoltaic harvesting of energy according to an example embodiment of the invention;

FIG. 9C is a simplified illustration of a system for photovoltaic harvesting of energy according to an example embodiment of the invention;

FIG. 10 is a simplified illustration of a system for photovoltaic harvesting of energy according to an example embodiment of the invention;

FIGS. 11A and 11B are simplified illustrations of systems for harvesting waste heat or infra-red radiation according to example embodiments of the invention;

FIG. 12A is a simplified illustration of a PL material emitting radiation according to an example embodiment of the invention;

FIG. 12B is a simplified illustration of an example configuration of PL material and PV material for dilution of photonic flux according to an example embodiments of the invention;

FIG. 12C is a simplified illustration of an example configuration of PL material and PV material for dilution of photonic flux according to an example embodiments of the invention;

FIGS. 13A and 13B are simplified illustrations of using properties of an Indium Tin Oxide (ITO) layer in example embodiments of the invention;

FIG. 13C is a simplified illustration of a shape of a PL absorber according to an example embodiment of the invention;

FIG. 13D is a simplified illustration of a shape of a PL absorber according to an example embodiment of the invention;

FIG. 13E is a simplified illustration of a wedge shaped PL absorber according to an example embodiment of the invention;

FIG. 13F is a simplified illustration of a wedge shaped cavity containing a PL absorber according to an example embodiment of the invention;

FIG. 13G is an illustration of radiation and heat flows in an example embodiment of the invention;

FIG. 13H is a graph illustrating spectral energy utilization of a system utilizing PL material and material according to an example embodiment of the invention;

FIG. 13I is a graph illustrating spectral energy utilization of a PV material according to prior art;

FIGS. 14A-14D are simplified illustrations of properties of materials used in example embodiments of the invention;

FIGS. 15A-15D are spectral graphs illustrating solar spectra altered by passing through material used in embodiments of the invention;

FIGS. 16A, 16B and 16C are graphs showing modeled efficiency of some devices according to example embodiments of the invention;

FIGS. 17A and 17B are a flowchart and a graph showing overall performance estimation of an example embodiment of the invention;

FIGS. 18A and 18B are graphs of emission spectra of YAG doped at different dopant concentrations according to some example embodiments of the invention;

FIG. 19A is a simplified illustration of an experimental setup used for measuring experimental results of example embodiments of the invention;

FIG. 19B is a graph showing results for temperature dependent absorption of CrNdYb:YAG according to an example embodiment of the invention;

FIG. 20A is a simplified illustration of an experimental setup used for measuring experimental results of example embodiments of the invention; and

FIG. 20B shows four graphs with results PL emission results measured by excitation by broad sunlight excitation and LDLS white light according to example embodiments of the invention.

### DESCRIPTION OF SPECIFIC EMBODIMENTS OF THE INVENTION

The present invention, in some embodiments thereof, relates to methods and devices for producing electricity from absorbed radiation and/or heat and, more particularly, but not exclusively, to using photo-luminescent (PL) material to absorb radiation and re-emit radiation onto one or more photovoltaic materials, and, more particularly, but not exclusively, to using PL material to absorb solar radiation, even at a point of solar radiation concentrated by heliostats to a top of a solar tower.

Overview

An aspect of the invention relates to systems and methods for energy conversion which include photoluminescent (PL) material for absorbing solar radiation and re-emitting PL radiation and photovoltaic (PV) material for absorbing the re-emitted PL radiation, and also a Heat Transfer Fluid (HTF) for carrying heat from the heated PL material to a system for conversion of HTF heat to energy. The aspect combines a thermally enhanced PL+PV electricity production system with a system for using absorbed heat to produce yet more electricity.

The system can be included in a solar energy harvesting system, and/or located at a top of a solar energy harvesting tower or at a focus of concentrated solar power.

In some embodiments the PV material can be off-the-shelf solar cells.

An aspect of the invention relates to thermally enhanced photoluminescence (TEPL) as a means to harvest solar energy at efficiency above the Shockley-Queisser (SQ) efficiency limit by coupling solar radiation to a low bandgap photoluminescence (PL) absorber, which re-emits the radiation onto an adjacent photovoltaic (PV) cell. A thermally enhanced photoluminescent (TEPL) material emits photons at a shorter wavelength and higher energy than photons it absorbs, potentially providing more energy for harvesting.

In some embodiments, using TEPL material potentially reduces heat load on the PV cell by converting longer wavelength radiation which would have heated the PV cell into shorter wavelength radiation which is absorbed by the PV cell and harvested as electric energy.

In some embodiments, the PL absorber absorbs solar radiation which excites electrons above the thermal excitation. In parallel, the PL absorber is heated by thermalization. The photonic and thermal excitation simultaneously results in a blue-shifted PL emission that is optionally matched to a PV cell, optionally a high bandgap PV cell operating at high voltage. A high photon current of a low bandgap PL absorber together with the high voltage of high bandgap PV results in a conversion efficiency above the Shockley-Queisser efficiency limit. In such embodiments, the energy in excess of the Shockley-Queisser efficiency limit apparently comes from thermal energy which is converted to photon energy and/or from voltage enhancement at the PV cell. The thermodynamic efficiency limit of TEPL reaches 70%, yet achieving high efficiency is challenging due to a spectral response of available materials at high temperatures. Part of this problem is a difference between energy gap materials and bandgap materials. While bandgap materials have a single bandgap, energy gap materials such as, by way of some non-limiting examples, rare earths or small molecules can have several electronic transitions that are pumped and emit simultaneously at various wavelengths. For example, using sensitized Neodymium (Nd⁺³) as a TEPL material, 30% of the emission at 1100K can be coupled to a GaAs solar cell. A large portion of the residual emission is at a wavelength of 1064 nm.

An aspect of the invention relates to cooling the PL material.

In some embodiments a desired temperature for the PL material is maintained, optionally by cooling and/or heating and/or insulating.

In some embodiments the desired temperature for the PL material is optionally maintained by passive cooling.

In some embodiments the desired temperature for the PL material is optionally maintained by active cooling.

In some embodiments the cooling is by radiation of heat from the PL material.

In some embodiments the cooling to the desired temperature is optionally achieved by tailoring transparency and/or reflectivity wavelengths of a window for removing heat by radiation.

In some embodiments the cooling is by using the heat for heating a fluid and/or gas and subsequently removing the heat from the PL material.

In some embodiments a fluid and/or gas is used to cool the PL material more at a front surface where radiation is input.

In some embodiments the fluid is optionally molten salt or super critical CO₂.

In some embodiments the cooling is by using the heat for heating a fluid and/or gas and subsequently using the heat of the fluid/gas.

In some embodiments the heat of the fluid/gas is used for various purposes, such as: generating electricity, heating houses, heating greenhouses, water desalination.

In some embodiments the desired temperature for the PL material is in a range typically referred to as waste heat, by way of a non-limiting example between 50 and 100, 150, 200 degrees Celsius, or in a range between 99 and 1500 degrees Celsius.

In some embodiments the desired temperature for the PL material is in a range typically considered inefficient for operating a photovoltaic device, such as, by way of a non-limiting example between 50 and 100, 150, 200, 500 and even 1,000 degrees Celsius.

An aspect of the invention relates to a concept of using heat from the PL material.

In some embodiments the heat is used to heat a gas or fluid and optionally act upon an electric generator such as a turbine.

An aspect of the invention relates to using a Thermally Enhanced Photoluminescence (TEPL) device for harvesting waste heat using photovoltaics.

In some embodiments the TEPL device is used to harvest waste heat, at temperatures in a range from 50 degree Celsius to 500 degree Celsius

In some embodiments the TEPL device uses PL material with a narrow band-gap for absorbing radiation between 1 micrometer and 2 micrometer wavelength.

In some embodiments the PL material emits blue-shifted PL radiation at wavelengths that are converted to electric energy by photovoltaic (PV) material.

An aspect of the invention relates to systems and methods of using a photoluminescent (PL) material which emits at more than one wavelength peak, and harvesting energy of multiple PL emission peaks by using multiple photovoltaic (PV) materials to absorb emitted PL radiation and produce electric current.

In some embodiments the PL material emits at a spectral window, for example a spectral window broader than, by way of a non-limiting example, 200 nm, and multiple photovoltaic (PV) materials are used to absorb the emitted PL radiation and produce electric current.

In some embodiments the PL material emits at a spectral window broader than, by way of some non-limiting examples, 200 nm, 300 nm, 400 nm, 500 nm, 600 nm, 700 nm.

In some embodiments the PL material is heated and placed to absorb and re-emit radiation, and the PL material emission peaks exhibit a blue-shift, that is, emit relatively more photons at wavelengths which are shorter, more energetic, than when the PL material is not heated. In some embodiments absorption bandgaps of the multiple PV materials are matched to at least some of the wavelengths of the multiple PL material emission peaks.

In some embodiments, some of the PL material emission peaks exhibit a strong blue-shift, and one or more of the PL material emission peaks exhibit a weak blue-shift. In some embodiments absorption bandgaps of the multiple PV materials are matched to at least some of the wavelengths of the multiple PL material emission peaks, that is, some PV material absorption bandgaps are matched to those of the PL material emission peaks which display a blue shift, and some PV material absorption bandgaps are matched to those of the PL material emission peaks which display a weaker blue shift.

In some embodiments the PL material is heated by contact with some hot material. In some embodiments the PL material is heated by convection.

In some embodiments the PL material is heated by absorbing radiation. In some embodiments the PL material is heated by absorbing radiation at a same time as some of the radiation is absorbed and re-emitted as PL radiation. In some embodiments, a source of absorbed radiation thus serves for both heating and causing PL radiation. In some embodiments, a source of absorbed radiation thus serves for both increasing the temperature and raising the chemical potential of emission.

In some embodiments the PL material is insulated so as to maintain temperature and/or elevate temperature above room temperature, and even to very high temperatures, all of which potentially augment the energy included in the PL radiation emission, which potentially augment electric current produced by absorbing PV material(s). In some embodiments the PL material is located within a vacuum chamber, which provides thermal insulation. In some embodiments the PL material is thermally insulated using an insulating material to maintain temperature and/or elevate temperature.

In some embodiments a heat load generated by the PL radiation at the PV material is lower than the heat load of direct solar illumination on the same PV material. In some embodiments the reduced heat load simplifies or eliminates a need for a cooling system and improves PV efficiency.

In some embodiments multiple PV cells are used to absorb the emitted PL radiation, at multiple bandgaps, to produce electric current. In some embodiments multiple PV materials, with optionally different bandgaps, are used as multiple layers in one or more multi-layered PV cells to absorb the emitted PL radiation, at multiple bandgaps.

In some embodiments the PL material is optionally surrounded by one or more reflective component(s), to reflect the PL radiation toward the PV material and/or to prevent the PL radiation from escaping the system, so as to potentially maximize use of the PL radiation for producing electric current. In some embodiments the reflective component(s) are optionally designed to reflect radiation at or around the PL emission peaks, while optionally being transparent, or more transparent, at other wavelengths. In some embodiments the reflective layers component(s) are optionally made with thin-film coatings designed to reflect radiation at or around the PL emission peaks. In some embodiments reflectors and/or filters are optionally placed to reflect PL emission from low bandgap solar cell to be absorbed at the high bandgap solar cell.

In some embodiments such reflective components optionally acts as windows, allowing radiation in to be absorbed by the PL material, and preventing PL radiation from exiting the system without either being absorbed by the PV material, being reabsorbed by the PL material, or heating the system by being absorbed.

In some embodiments the reflective components optionally acts as windows, allowing solar radiation in to be absorbed by the PL material, and preventing PL radiation from exiting the system without either being absorbed by the PV material, being reabsorbed by the PL material, or heating the system by being absorbed.

In some example embodiments a combination of a PL material and two different PV materials include Nd⁺³, which at room temperature emits among other wavelengths, at 950 nm and 1064 nm. At high temperatures the Nd⁺³ 1064 nm emission peak is unchanged and the 950 nm emission is partly blue shifted to 820 nm wavelengths. For such dual peak radiation, two solar cells can be matched. A first solar cell with a Si PV material has a matching bandgap for absorbing the 1064 nm wavelength peak, and a second solar cell, with GaAs PV material, which has a matching bandgap for absorbing the 820 nm wavelength peak.

In some embodiments Si is optionally replaced with some other PV material with a bandgap of approximately 1 eV.

In some embodiments GaAs is optionally replaced with some other PV material having a bandgap of approximately 1.4 eV, such as a perovskite material or a perovskite structured material.

In some embodiments a radiation concentrator, such as a solar concentrator, is optionally used to concentrate radiation such as solar radiation on the PL material.

An aspect of the invention relates to systems and methods of using a PL material which emits at more than one wavelength peaks, and harvesting energy of multiple PL emission peaks by using multiple photovoltaic (PV) materials to absorb emitted PL radiation at a top of a solar tower.

In some embodiments a radiation concentrator, such as a solar concentrator, is optionally used to concentrate radiation such as solar radiation on the PL material. In some embodiments the solar concentrator(s) are heliostats, reflecting the sun's radiation to the PL material at the top of the solar tower.

An aspect of the invention relates to constructing an energy harvesting system which tailors photovoltaic absorption and energy production capability to PL emission capability.

In some embodiments a radiation concentrator, similar to a solar concentrator, is optionally used to concentrate radiation from the PL material onto the PV material.

In some embodiments geometry of the PV cell or PV material is configured to dilute radiation from PL material onto the PV material.

In some embodiments dilution of the photonic flux is used to enable using low cost PVs in a concentrated radiation system.

In some embodiments a PV absorption surface is optionally at an angle to a direction of emission from a PL emitter, potentially reducing photonic flux impinging on the PV.

In some embodiments diffusers or scatterers are optionally used to dilute photonic flux.

An aspect of the invention relates to constructing an energy harvesting system which includes a transparent Near-IR absorbing layer such as ITO (Indium Tin Oxide), for potentially absorbing Near Infra Red (NIR) radiation.

In some embodiments a front window is optionally used for NIR absorption.

In some embodiments a back of the radiation collection component includes an ITO layer.

An aspect of the invention relates to constructing an energy harvesting system which a combination of Concentrated Solar Power (CSP) and CPV (concentrated photo-voltaic) in one system. In some embodiments the system potentially provides heat for thermochemically producing hydrogen.

In some embodiments a CSP-driven hydrogen production is used by water splitting (WS). In some embodiments a CSP-driven redox-pair oxide system is used to split CO₂, called carbon dioxide splitting (CDS).

In some embodiments combined CO₂/H₂O splitting is optionally used for production of CO or syngas (synthetic gas), respectively.

An aspect of the invention relates to constructing an energy harvesting system which includes a low effective index (n approximately equals 1) for reducing radiation losses such as wave-guided radiation losses.

An aspect of the invention relates to constructing an energy harvesting system which includes coating PL material with a nanoparticle coating or embedding nanoparticles in PL material to scatter impinging radiation and distribute the radiation along an absorption area of a PV cell.

In some embodiments a PL absorber is optionally coated to reduce thermal energy.

In some embodiment the coating is with a coating material having a spectrally-selective solar absorption optionally configured to transfer incident solar radiation between 650 nm and 1100 nm, to enable solar radiation to reach the PV cell directly, and to reflect at wavelengths longer than about 1100 nm.

In some embodiments the coating material is optionally a material as described in published PCT patent application WO 2017/147463 of Chen et al, titled SOLAR THERMAL AEROGEL RECEIVER.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

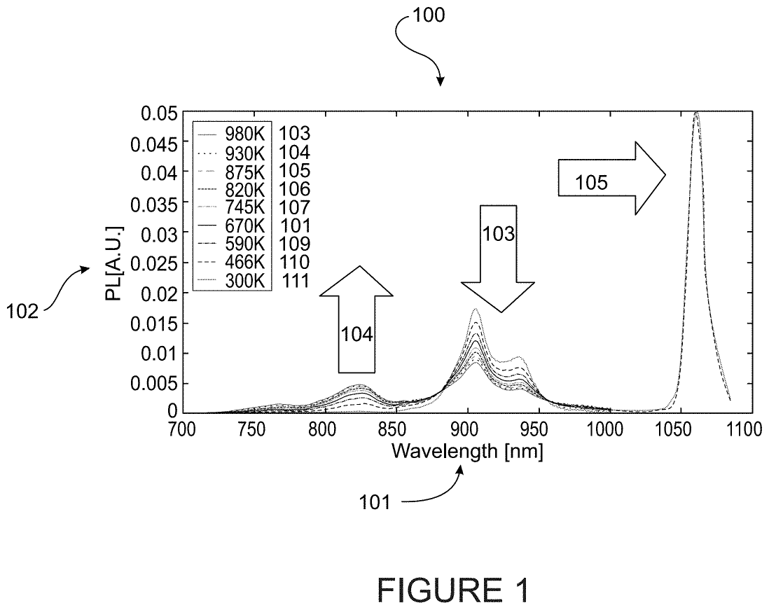

Reference is now made to FIG. 1, which is a graph showing power spectra lines of Nd⁺³ photoluminescence at various temperatures according to an example embodiments of the invention,

The graph 100 of FIG. 1 has an X-axis 101 showing wavelength in nanometers (nm) and a Y-axis 102 showing a qualitative measure in arbitrary units.

FIG. 1 depicts power spectra lines 103-111 of Nd⁺³ photoluminescence at various temperatures, showing a blue-shift from a 950 nm wavelength emission peak 103 to a 820 nm emission peak 104 and a blue-shift of a 1064 nm emission peak 105 into shorter wavelength emission peaks upon heating. Other emission lines of Nd⁺³ (not shown in FIG. 1) are at 530 nm and 580 nm.

FIG. 1 shows that as the temperature rises, more photons are emitted at 820 nm and less photons are emitted in the band 850 nm-950 nm.

An example configuration for harvesting energy gap materials with few electronic transitions, such as rare earths, is by multi-junction configuration. For the example of sensitized Nd⁺³, dual junction solar cells with bandgaps matching 850 nm and 1100 nm wavelength are an optional fitting match.

In an example embodiment of the invention—we place a TEPL material inside a cavity together with one or more solar cells having two or more different bandgaps, in order to benefit from thermally induced voltage enhancement at different emission bands. Specifically, the TEPL material is optionally placed at a center of a concentrated solar radiation inside a cavity with reflective walls at wavelengths that match the TEPL spectrum. The TEPL material is excited by solar radiation elevating its temperature and chemical potential; which is a photoluminescence excitation above thermal excitation. In some embodiments the cavity is optionally surrounded by solar cells and reflective mirrors in order to minimize radiation losses from the cavity. Optionally the walls of the cavity have at least two solar cells having at least two different bandgaps. For example, GaAs and Si solar cells are a good match for Nd⁺³-based TEPL. In this example, the GaAs collects the thermally up-converted light, at wavelengths shorter than 850 nm, while the Si cell collects the portion of light that is energetically below the GaAs bandgap, at wavelengths between 850 nm and 1100 nm.

This example configuration overcomes the SQ efficiency limit even at moderate temperatures, such as above 100 C. This is because the Si solar cell can reach its SQ limit while any additional current at the GaAs cell gives extra energy.

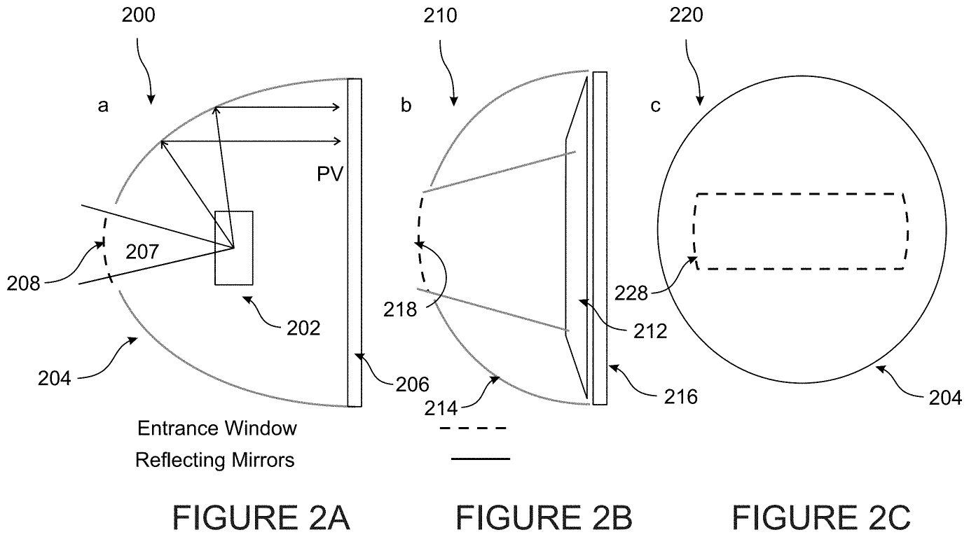

Reference is now made to FIG. 2A, which is a simplified illustration of a system 200 for photovoltaic harvesting of energy according to an example embodiment of the invention.

FIG. 2A is a cross-sectional side view of the system 200.

FIG. 2A depicts a simple configuration of a paraboloid-shaped TEPL-based converter. The TEPL material (rectangular box 202) is placed inside a paraboloid shaped cavity 204. The cavity 204 includes the TEPL material 202 and solar cells 206, optionally with two or more different bandgaps (marked as ‘PV’ 206).

In some embodiments an entrance window 208 is optionally made from highly reflective (HR) coating, optionally highly reflective at a low energy band-edge of the TEPL material 202.

In some embodiments an entrance window 208 is optionally made from low reflectivity or made anti-reflective at wavelengths above the bandgap of the PL material, for light coming from the solar field within an angle 207.

In some embodiments the AR/HR coating is at the band edge of the PV to allow direct excitation of the PV by low energy solar radiation that is still above the PV's bandgap.

In some embodiments the AR coating is configured to be anti-reflective between 400 nm and 1100 nm for the solar field angles within the angle 207 (or even between 400 nm and 1700 nm) and HR coating at the PL emission wavelength between 700 nm and 1100 nm at angles other than the field angles within the angle 207.

For a non-limiting optional example configuration of sensitized Nd⁺³ based TEPL 202 with Si and GaAs solar cells 206 inside the cavity, the entrance HR coating is optionally highly reflective in a range approximately between 950 nm-1100 nm. In some embodiments, the HR coating has high reflectivity at a range approximately between 950 nm-2500 nm and even between 950 nm-5000 nm. Such coating potentially reduces thermal losses from radiation.

Reference is now made to FIG. 2B, which is a simplified illustration of a system 210 for photovoltaic harvesting of energy according to an example embodiment of the invention.

FIG. 2B is a cross-sectional side view of the system 210.

FIG. 2B depicts a simple configuration of a planar TEPL 212 inside a hemispherical cavity 214. Optional sharp trapeze edges of the planar-shaped TEPL 212 are designed to potentially guide emissions from inside the TEPL material 212 to PV cell(s) 216.

In some embodiments surface roughness is used on the surface of the TEPL 212 to enhance emission extraction and reduce wave-guiding of the TEPL emission.

In some embodiments wavelength-selective scatterers, such as plasmonic nanoparticles, are optionally embedded in the TEPL material 212 to scatter light at wavelengths that match the high bandgap solar cell 216, while other radiation at other wavelengths is optionally kept in the TEPL material 212. Such a selective scattering potentially improves conversion efficiency by reducing self-absorption of light that matches the high bandgap solar cell 216.

Reference is now made to FIG. 2C, which is a simplified illustration of a system 220 for photovoltaic harvesting of energy according to an example embodiment of the invention.

FIG. 2C is a front view of the system 220.

FIG. 2C shows a typical entrance window 228 matched for a typical acceptance angle in solar fields, which in some embodiments is optionally 120 degrees horizontal and 30 degrees vertical. In such a configuration two or more PV cells (not shown in FIG. 2C). optionally with different bandgaps, are optionally distributed evenly at the PV cell side, referenced 216 in FIG. 2B.

The dashed lines 208 218 228 in FIGS. 2A, 2B, 2C show the entrance windows, in some embodiments highly reflective (HR), in some embodiments at a range of approximately 950 nm-1100 nm.

In some embodiments low dopant concentrations of emitting molecules are optionally used for enhancing quantum efficiency.

In some embodiments a TEPL material is selected and shaped to provide a propagation length between a few millimeters and a meter inside the TEPL material.

In some embodiments the TEPL material can optionally be as thin as few microns, up to as thick as few meters.

In some embodiments a size and shape of the TEPL material is designed to provide a radiation propagation path in the TEPL that is longer than an absorption length of typical incoming radiation wavelength.

In some embodiments a size and shape of the TEPL material is designed to provide a radiation propagation path in the TEPL material that is shorter than an absorption length of PL-emitted or TEPL-emitted radiation wavelengths, namely self-absorption or re-absorption.

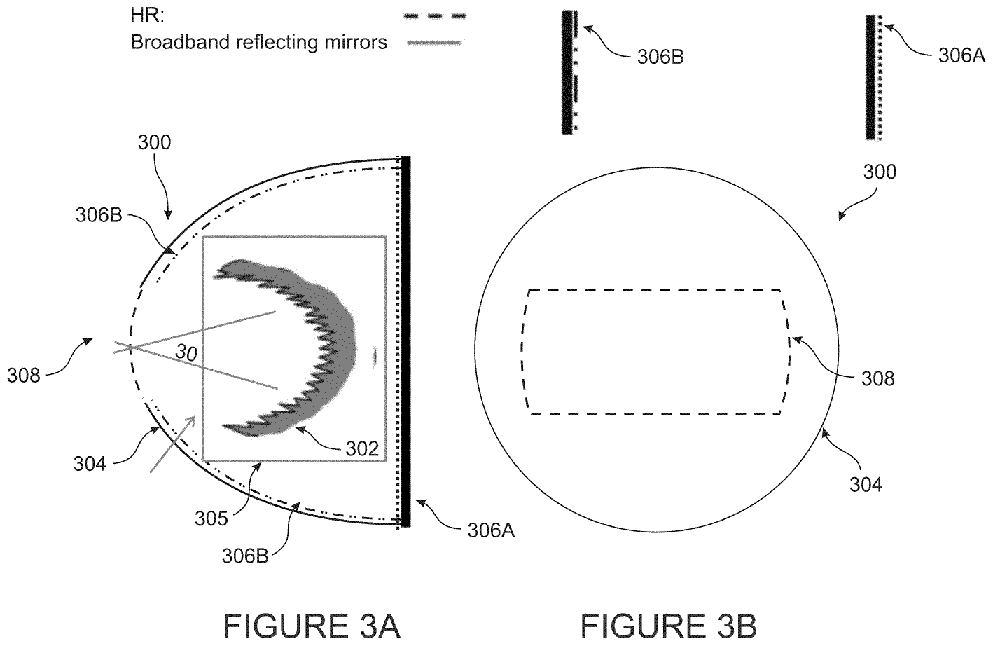

Reference is now made to FIGS. 3A and 3B, which are simplified illustrations of a system 300 for photovoltaic harvesting of energy according to an example embodiment of the invention.

FIG. 3A is a cross-sectional side view of the system 300.

FIG. 3B is a front view of the system 300.

FIG. 3A shows another example embodiment of the invention, including a paraboloid shaped cavity 304 with a radiation entrance window 308, TEPL material 302 and PV cell(s) 306A 306B.

FIG. 3B shows a front view of the radiation entrance window 308 in the cavity 304.

In some embodiments the paraboloid shaped cavity 304 is a mirror, optionally except for the window 308, and the TEPL material 302 is placed at a location including the focal point of the paraboloid shaped cavity 304.

In some embodiments the cavity 304 optionally contains a transparent vacuum chamber 305 within which the TEPL material 302 is placed. In some embodiments the vacuum chamber 305 is coated with anti-reflection (AR) coating.

In some embodiments the TEPL material 302 is optionally based on sensitized Nd⁺³ TEPL material 302.

In some embodiments the PV cell(s) optionally including Si 306A, and GaAs 306B PV materials.

In some embodiments the PV cell(s) which include the Si 306A photovoltaic (PV) material, optionally include a bandpass filter passing at a wavelength range of approximately 850 nm-1100 nm.

In some embodiments the PV cell(s) which include the GaAs 306B PV material, optionally include a back reflector. In some embodiments the PV cell(s) which include the GaAs 306B PV material, optionally include a front highly reflective (HR) filter—optionally highly reflecting at a wavelength range of approximately 850 nm-1100 nm.

FIG. 3A shows an optional shape of the TEPL material 302 structured to enhance absorption of solar radiation by double or multiple reflection.

In some embodiments the thickness of the TEPL material 302 is optionally on an order of the absorption length of solar radiation and optionally shorter than the re-absorption length at the TEPL emission wavelength, which for a 0.1%-1% weight concentration of Nd⁺³ is between a few millimeters and a few centimeters.

In some embodiments, for ultra-high quantum efficiency, the Nd⁺³ concentrations are optionally further reduced, which potentially enable a TEPL thickness of tens of centimeters.

In some embodiments, a shape of the TEPL material is elongated in order to enhance a geometric view of the TEPL material in relation to the solar cells at the walls of the cavity, potentially thereby enhancing the collection efficiency of the solar cell.

In some embodiments, the lower bandgap solar cells are optionally coated with HR coating for a wavelength shorter than the higher bandgap solar cells. For the example embodiment of Si and —GaAs solar cells, the Si solar cell is optionally coated with HR for the wavelengths shorter than 850 nm. This limits the absorption of energetic photons at the Si and allows that wavelength to pass onto the GaAs solar cells.

In some embodiments of the example embodiment of FIGS. 3A and 3B, the entrance window 304 HR coating optionally highly reflects between 950 nm and 1100 nm, optionally matching the low energy band-edge emission of Nd⁺³.

In some embodiments the TEPL material is placed inside a thermally insulating transparent chamber in order to elevate its temperature by thermalization, leading to a stronger blue-shift emission and increased total efficiency.

In some embodiments there is a thermally insulating gap between the PL material 302 and the PV cell(s) 306 to reduce the heat load on the PV cell(s).

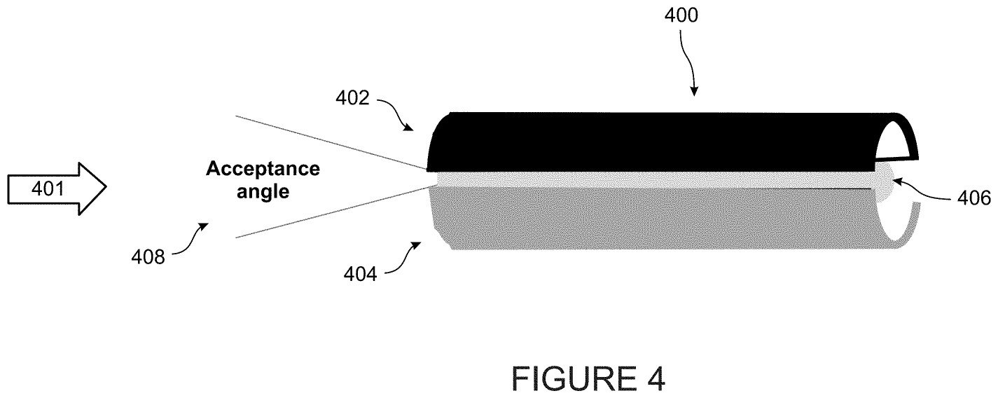

Reference is now made to FIG. 4, which is a simplified illustration of a system 400 for photovoltaic harvesting of energy according to an example embodiment of the invention.

FIG. 4 shows a cylindrical configuration, where solar radiation 401 reaches an end of a cylindrical shape TEPL material 406, being absorbed within an acceptance angle 408.

In some embodiments the cylindrical TEPL material 406 is placed inside a cylindrical tube, optionally even a vacuum tube, for reaching high temperatures by thermal insulation.

In some embodiments, two or more solar cells 402 404, optionally with different bandgaps, are placed around the circumference of the cylindrical TEPL material 406.

In some embodiments the low bandgap solar cell is coated with HR coating at wavelengths that match the high bandgap second solar cell, thereby reflecting the matched emission onto the high bandgap solar cell.

Such an elongated configuration potentially benefits from a long absorption length of incoming radiation and/or a short propagation length of the emission, which minimize self-absorption losses.

In some embodiments elongated shapes can be structured to have a similar benefit, for example, an elongated rectangular box shape.

Comparing the example configuration of FIG. 4 with an example configuration of a TEPL conversion system where only a single high bandgap solar cell is used, we estimate that a dual bandgap cavity exceeds in efficiency the single high bandgap solar cell TEPL configuration. Specifically, by way of a non-limiting example a system using a TEPL emitter such as sensitized Nd⁺³ operating at moderate temperatures between 500 C and 1000 C we estimate that the conversion efficiency exceeds 35%.

In some embodiments TEPL material is further sensitized by adding additional absorbing materials into the TEPL bulk. Such materials absorb incoming radiation and transfer the energy to the emitter.

In some embodiments energy transfer between the sensitizer and the emitter can be near-field energy transfer, such as Forester energy transfer or Dexter energy transfer.

In some embodiments the energy transfer between the sensitizer and the emitter is a radiative energy transfer. Conventional sensitizers, which are suitable for example for Nd⁺³ and Yb emitters include rare earths, transition metals, molecules of other PL materials and quantum dots with emission peak that at least partly overlap with absorption peak of the emitter.

Some non-limiting examples of sensitizers are Chromium (Cr) and Cerium (Ce).

Some non-limiting examples of rare earth sensitizers include Ytterbium (Yb), Erbium (Er), Europium (Eu), Praseodymium (Pr), Terbium (Tb), Thulium (Tm), Samarium (Sm), Gadolinium (Gd), Holmium (Ho), Lutetium (Lu).

Quantum dots include, for example, wide bandgap semiconductor nanocrystals, such as GaAs, AlGaAs, GaAsP, AlGaInP, GaP, GaAsP, GaN, InGaN, ZnSe, InGaN, SiC, Diamond, Boron Nitride, AlN, and AlGaN.

In some embodiments use of a nanocrystal size of quantum dots as sensitizers potentially extends the efficacy of the TEPL material toward higher temperatures.

In some embodiments, encapsulation of the TEPL material, such as in SiO₂, potentially extends efficacy of the TEPL material toward higher temperatures.

In some embodiments bulk material of wide bandgap semiconductors with a direct bandgap is optionally used as sensitizers. This is due to the wide bandgap semiconductors' high PL efficiency and relative durability at high temperatures. By way of a non-limiting example, Gallium Nitride (GaN), Aluminum Nitride (AlN), GaInN, and AlGaInP, are conventionally used as light emitting diodes at high temperatures, thus are suitable to be used in TEPL material in an example embodiment.

In some embodiments the multi-peak emission is from both the sensitizers and the emitters. For example, using a Cr:Yb based TEPL. In such an embodiment Cr⁺³ absorbs a green-red part of the spectrum. At high temperatures, the absorbed energy is partially emitted at 700 nm-1100 nm by the Cr and partially transferred to the Yb, which emits between 850 nm-1000 nm. At room temperature Yb emits between 950 nm-1100 nm. Such an example combination has a double peak emission which is optionally harvested by GaAs and GaInAs PV materials, optionally in a GaAs/GaInAs tandem cell, or by GaAs and Si materials, optionally in GaAs cells and Si cells or in a GaAs/Si tandem cells.

In some embodiments, multi-junction tandem PV cells are placed in the cavity. For the Nd⁺³ example with emissions at 530 nm, 580 nm, 850 nm, and 1064 nm, a multi-junction PV cell combining InGaP, GaAs, and GaInNAs, or InGaAs harvests each emission at a corresponding bandgap, with potentially maximal efficiency.

In some tandem configurations the PV junctions are optionally arranged to be one behind the other along an optical path of radiation. Such tandem configurations can come as separate components or as a single multilayer device.

In some embodiments a transparent GaAs solar cell above a Si solar cell, in some embodiments with a gap between them, are optionally used as a cost effective dual junction device. In some embodiments of such a configuration transparent conducting electrodes such as ITO (Indium Tin Oxide) electrodes are optionally used.

In some example embodiments, the TEPL material includes wavelength-selective scattering nano-particles. Resonant scattering with minimal absorption loss is optionally achieved by using small plasmonic particles such as silver nanoparticles or silver/silica nanoparticles. In some embodiments, Titanium Nitride (TiN) is a choice for high-temperature selective-wavelength-scattering nano-particles. Optionally, gold or silver nanoparticles, optionally encapsulated in Silica are used as resonant scatterers.

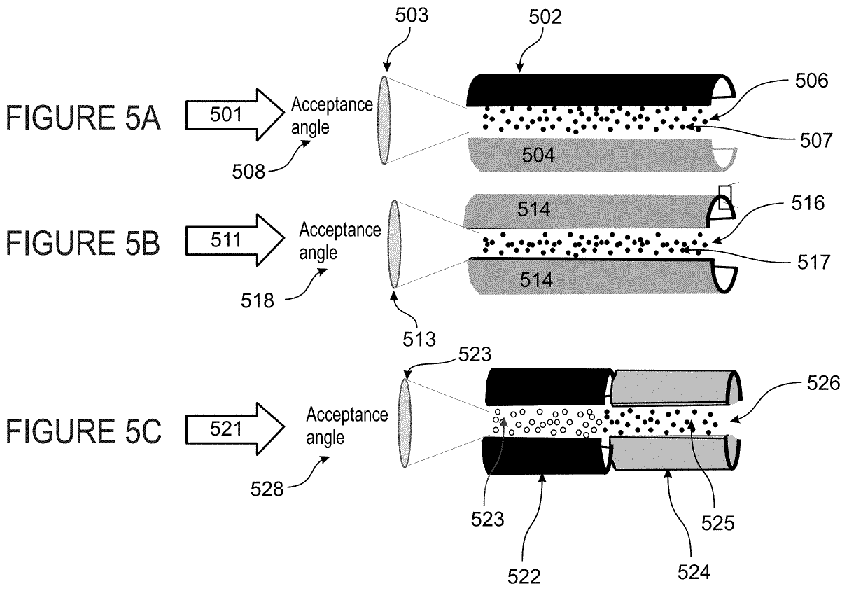

Reference is now made to FIGS. 5A, 5B and 5C, which are simplified illustration of systems for photovoltaic harvesting of energy according to some example embodiments of the invention.

FIG. 5A shows a cylindrical configuration, where solar radiation 501 reaches an end of a cylindrical shape TEPL material 506, being absorbed within an acceptance angle 508.

In some embodiments, two or more photovoltaic (PV) cells 502 504, optionally with different bandgaps, are placed around the circumference of the cylindrical TEPL material 506.

FIG. 5A shows a waveguide configuration, with additional resonance scattering particles 507 embedded within and/or on the surface of the TEPL material 506. Such a resonance scattering allows part of the radiation to travel in the waveguide until the radiation is absorbed, while other radiation is not waveguided and scatters out to the PV material(s) in the PV cells 502 504.

In some embodiments the PV cells 502 504 are designed so that, by way of some non-limiting example:

a first PV cell 502 optionally includes GaAs with a bandgap of 1.35 eV; and

a second PV cell 504 optionally includes Si with a bandgap of 1.1 eV, optionally with a highly-reflective (HR) filter, the HR filter optionally being highly reflective in a wavelength range of 400 nm-850 nm.

In some embodiments the scattering resonance wavelength is optionally tuned to a wavelength that matches only the high/wide bandgap PV material. The radiation portion for which the high/wide bandgap PV material has a high conversion efficiency is scattered by optional nanoparticles from the waveguide to the matching PV material. On the other hand another portion of the spectrum, optionally including a portion of solar and TEPL radiation, optionally continues to travel along the waveguide until it is absorbed or re-absorbed. In some embodiments the re-emitted light may have a spectral portion which matches the wide band gap PV and may be scattered out of the waveguide. Such a photon-recycling dynamic channels more light to the wide bandgap solar cell and improves the overall efficiency, in terms of photons absorbed to electrons produced.

In some embodiments a radiation concentrating component 503 optionally concentrates the incoming radiation 501 onto the TEPL material 506.

FIG. 5B shows a cylindrical configuration, where solar radiation 511 reaches an end of a cylindrical shape TEPL material 516, being absorbed within an acceptance angle 518.

In some embodiments, a PV cell 504 optionally includes a stack of two PV materials with different bandgaps, placed around the circumference of the cylindrical TEPL material 506. In some embodiments the PV cell 504 optionally includes GaAs with a bandgap of 1.35 eV and Si with a bandgap of 1.1 eV.

FIG. 5B also shows a waveguide configuration, with additional resonance scattering particles 517 embedded within and/or on the surface of the TEPL material 506. Such a resonance scattering allows part of the radiation to travel in the waveguide until the radiation is absorbed, while other radiation is not waveguided and scatters out to the PV material(s) in the PV cell 514.

FIG. 5B shows an example embodiment of Si/GaAs or GaInAs/GaAs solar cell(s) 514 and a TEPL material 516 based on sensitized Nd⁺³. In the example of FIG. 5B the resonance of the scattering particles is optionally tuned to scatter wavelengths between 700 nm and 850 nm. The scattered light reaches a GaAs PV cell 514 with minimal propagation and minimal self-absorption in the TEPL material 516. On the other hand, the non-scattered light propagates along the waveguide until absorbed. Such a differentiation between the higher energy portion of a spectrum and a lower energy portion of the spectrum potentially results in more total energy extraction by the PV cells.

In some embodiments a radiation concentrating component 513 optionally concentrates the incoming radiation 511 onto the TEPL material 516.

FIG. 5C shows a cylindrical configuration, where solar radiation 521 reaches an end of a cylindrical shape TEPL material 526, being absorbed within an acceptance angle 528.

In some embodiments, first PV cell(s) 522 are optionally placed along the TEPL material 526 closer to the entrance of the radiation 521, and second PV cell(s) 524 are optionally placed along the TEPL material 526 further from the entrance of the radiation 521.

FIG. 5C also shows a waveguide configuration, with additional resonance scattering particles 523 525 optionally embedded within and/or on the surface of the TEPL material 526.

In some embodiments different PV cells 522 524 with different bandgaps are geometrically separated, and optionally different corresponding selective scattering particles 523 525 are embedded in locations matched to the locations and bandgaps of the PV cells.

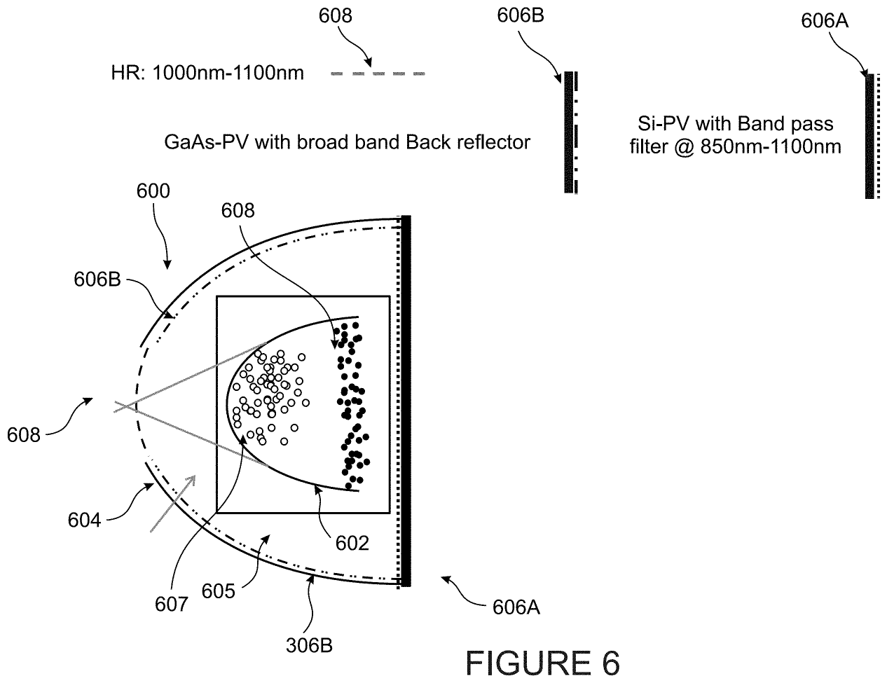

For a Nd⁺³ example, a GaAs PV cell 522 is optionally placed next to an entrance edge of the TEPL material and a Si PV cell 524 is optionally placed at a remote edge (such as shown at the bottom of FIG. 5C and in FIG. 6). In such an example configuration, a wavelength-selective scatterer 523 which scatters at a wavelength range approximately between 700 nm and 850 nm is optionally embedded next to the entrance for radiation 521, and additional scatterers 525 at a wavelength range approximately between 850 nm and 1064 nm are optionally placed toward the remote edge. FIGS. 5C and 6 show examples of such configurations. In some embodiments, the scatterers 523 525 are optionally placed in a geometric configuration where scattered light is guided to reach a matching solar cell 522 524. In some embodiments the guiding is optionally by a mirror that reflects the scattered light to the matching PV cell, or by a separation between locations of scatterers 523 525 that matches a separation between PV cells 522 524.

In some embodiments a radiation concentrating component 523 optionally concentrates the incoming radiation 521 onto the TEPL material 526.

Reference is now made to FIG. 6, which is a simplified illustration of a system 600 for photovoltaic harvesting of energy, locating different scatterers at different locations, according to an example embodiment of the invention.

FIG. 6 is a cross-sectional side view of the system 600.

FIG. 6 shows a paraboloid shaped cavity 604 with a radiation entrance window 608, TEPL material 602 and PV cell(s) 606A 606B.

In some embodiments the paraboloid shaped cavity 604 is a mirror, optionally except for the window 608, and the TEPL material 602 is placed at a location including the focal point of the paraboloid shaped cavity 604.

In some embodiments the cavity 604 optionally contains a transparent vacuum chamber 605 within which the TEPL material 602 is placed. In some embodiments the vacuum chamber 605 is coated with anti-reflection (AR) coating.

FIG. 6 shows an illustration of locating different scatterers 607 608 at different locations in the system 600 and corresponding location of PV cells 606A 606B.

In some embodiments a first type of scatterer 607 optionally includes wavelength selective scattering nano-particles which scatter at a wavelength range of 700 nm-850 nm.

In some embodiments a second type of scatterer 608 optionally includes wavelength selective scattering nano-particles which scatter at a wavelength range of 850 nm-1100 nm.

In some embodiments the window 608 includes HR coating at a highly reflective at a range of 1000 nm-1100 nm.

In some embodiments the PV cell(s) 606A include Si PV material. In some embodiments the PV cell(s) 606A optionally include a band-pass filter at a wavelength range of 850 nm-1100 nm.

In some embodiments the PV cell(s) 606B include GaAs PV material. In some embodiments the PV cell(s) 606B optionally include a broad band back reflector.

In some embodiments the system 600 is optionally constructed by depositing at least one nanoparticle type scatterer 607 which optionally has, for example, a scattering cross section with a full-width half maximum of about 1 nm to about 700 nm and a center wavelength from about 390 nm to about 1900 nm in or on the surface of a TEPL material with a transmittance of about 60% to about 100% (e.g., 65%, 70%, 75%, 80%, 85%, 90%, or 95%) from about 400 nm to about 1900 nm.

In some embodiments other scattering mechanisms 608 are optionally used to achieve scattering.

Additional example embodiments optionally use scattering mechanisms such as Mie and Rayleigh scattering, which scatter short wavelength light at higher scattering cross sections than long wavelength light.

In some embodiments, a waveguide configuration of TEPL material has scattering nanoparticles according to Rayleigh enhanced scattering at short wavelength that scatter more at a wavelength matching the high bandgap PV material and less at longer wavelength. In such a configuration, the length of the TEPL waveguide is optionally longer than the scattering length at the shorter wavelength and optionally the waveguide length is shorter than a self-absorbing length at longer wavelength. This way, the energetic portion of the light scatters and reaches the high bandgap solar cell. Radiation at longer wavelength is less effected by the Rayleigh scattering, and propagates until it is absorbed in the TEPL material. The TEPL material re-emits the absorbed radiation, including an energetic portion, which again is scattered to the PV cell. Such photon recycling potentially improves overall efficiency.

A Cooling System for TEPL Material.

In some configurations, based on bandgaps of the PV material(s) and the energy gap of the TEPL material, a desired temperature range for the TEPL material is optionally determined and optionally maintained. Below the desired temperature range efficiency at the solar cell may potentially be reduced due to a potential reduction in the thermally induced blue shift at the PL material. Above the desired temperature, energetic photons potentially thermalize at the PV material, raising temperature and reducing efficiency of the PV material.

In some embodiments the TEPL material is optionally cooled.

Radiation Cooling

In some embodiments thermal radiation of the TEPL material at high emissivity IR regions is optionally used to cool the TEPL material, in some embodiments even to maintain an upper limit on temperature of the TEPL material. For example, an energy conversion device operating at 100 suns concentration leads to approximately 100 kW/m². At 20% efficiency, approximately 80 kW/m² should optionally be evacuated from the device. A high emissivity between 3 μm and 10 μm by Black Body radiation flux implies an upper limit temperature of 1200K, for which thermal emission is 80 kW/m².

In some embodiments an entrance window to a cavity containing TEPL material optionally has a reflective coating at wavelengths longer than the bandgap of the low bandgap-PV material.

In some embodiments the reflective coating at the entrance window is reflective at wavelengths of the energy gap of the TEPL material.

In some embodiments, anti-reflective coating for sub bandgap radiation wavelengths is optionally placed at the cavity walls, potentially allowing IR thermal radiation to escape and cool the TEPL material.

In some embodiments, selecting the energy gap of the TEPL material and the PV material(s) bandgap is optionally performed so as to reduce a heat load on the TEPL material. At a given temperature, part of the solar spectrum that is absorbed by the TEPL material heats it through thermalization (Stokes shift) and part of the solar spectrum cools it through optical refrigeration (Anti-Stokes shift). In some embodiments a balance between the heating by thermalization (Stokes shift) and the optical refrigeration (Anti-Stokes shift) is optionally calculated to lower and/or minimize the heat load and/or to improve energy conversion efficiency.

In some embodiments the emissivity of the TEPL material is high at longer wavelengths than that of the low bandgap PV material.

In some embodiments the emissivity of the TEPL material is high between 2 μm and 12 μm.

Energy Harvesting and Active Cooling

In some embodiments a steam turbine system is optionally used to cool the TEPL material, the temperature of which may reach 1000 C. The steam generated using the high temperature is optionally used to drive a turbine, and also cool the TEPL material. In such a configuration hot TEPL material is optionally placed in a pressure chamber, optionally immersed in water or some other cooling liquid.

In some embodiments, steam is generated at the surface of the TEPL material and steam pressure in the pressure chamber runs a turbine. Optionally, steam energy may be converted to electricity or used for supply of hot water to homes and industry. Optionally the steam turbine is a close-loop Rankine-cycle configuration with a condenser which acts as a heat exchanger using cooled water and supplying hot water.

In some embodiments a heat transfer fluid (HTF) is a molten salt which carry heat from the TEPL material to a heat exchanger and on to steam for running a turbine.

In some embodiments the HTF is super critical CO₂.

In some embodiments the HTF is steam.

It is emphasized that other heat engines can replace a turbine for generating energy from the generated heat at the TEPL material.

In some embodiments, excessive heat at the heat exchanger or at the TEPL material is used for water desalination. In such embodiments, a heat exchanger optionally generates steam from saline water, and the steam is optionally collected and condensed into water.

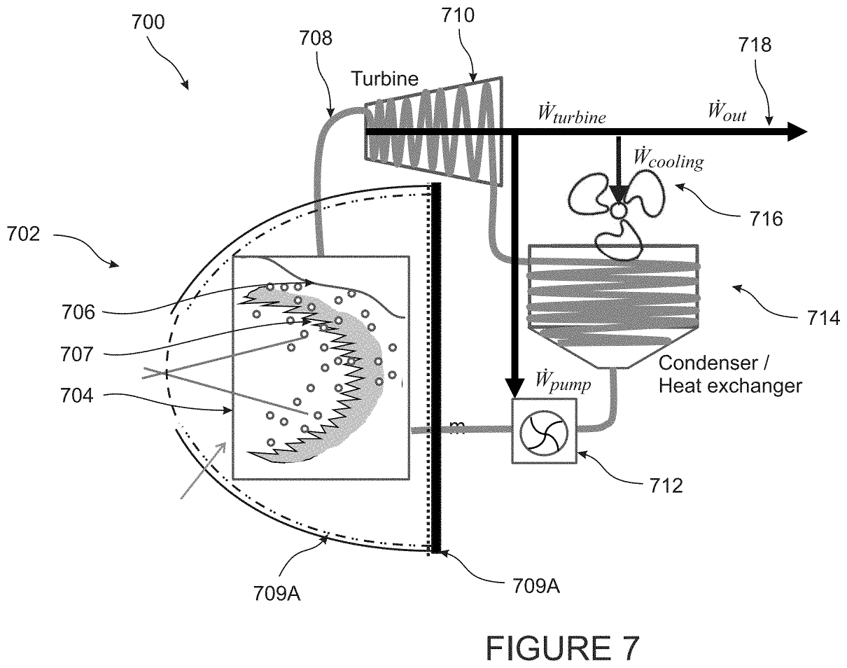

Reference is now made to FIG. 7, which is a simplified illustration of a system 700 for photovoltaic harvesting of energy and using heat transfer fluid to harvest additional energy according to an example embodiment of the invention.

FIG. 7 is a cross-sectional side view of the system 700.

FIG. 7 shows a sub-system 702 for photovoltaic harvesting of energy as described above with reference to several example embodiments, also including a chamber 704 with liquid 706 or steam 706.

The sub-system 702 for photovoltaic harvesting of energy includes PL material 707 for absorbing radiation, heating up, and emitting radiation for PV cells 709A 709B to generate PV electricity.

The liquid or steam 706 is heated by proximity to the PL material 707.

In some embodiments the liquid or steam 706 is optionally cycled 708, as liquid or as steam, to a turbine 710 for harvesting still more energy from the heated liquid.

In some embodiments the liquid or steam 706 may be evaporated by the heat in the chamber 704 and be cycled to the turbine as steam.

In some embodiments the liquid or steam 706 may be a gas used for transferring the heat.

In some embodiments the liquid or steam 706 is optionally pumped through the turbine 710 and chamber 704 by a pump 712.

In some embodiments an optional condenser or heat exchanger may be used to condense steam

In some embodiments the chamber 704 is transparent. In some embodiments the chamber 704 includes AR coatings and/or reflective coatings as described with reference to embodiments of the PV systems described herein.

In some embodiments the chamber 704 walls include AR coating in a wavelength range of 350 nm-1100 nm. In some embodiments the chamber 704 walls include AR coating in a wavelength range of 350 nm-1700 nm.

FIG. 7 depicts an example embodiment of a TEPL system 702 combined with a steam turbine 710 that drives a water pump Wₚᵤₘₚ 712 and cooling ventilation W_{cooling} 716 and produces electric energy Wow 718.

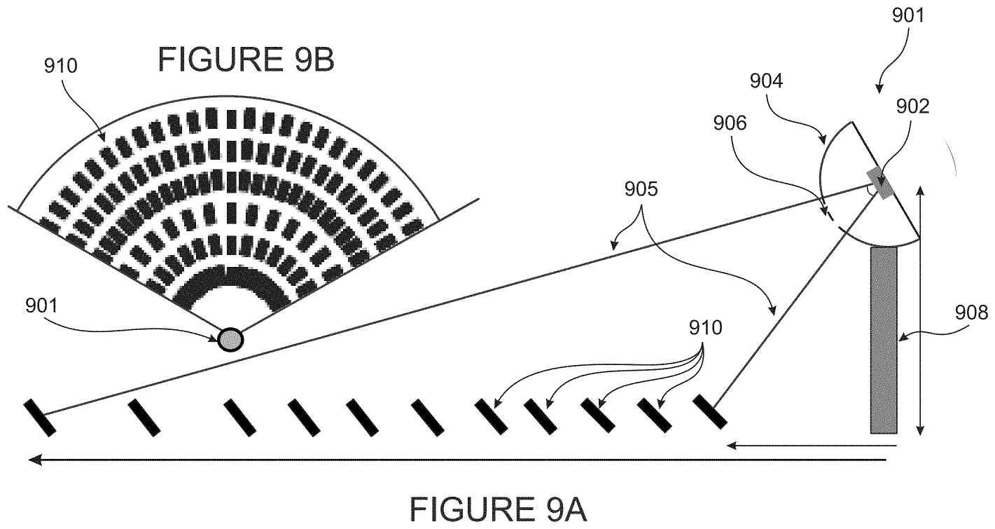

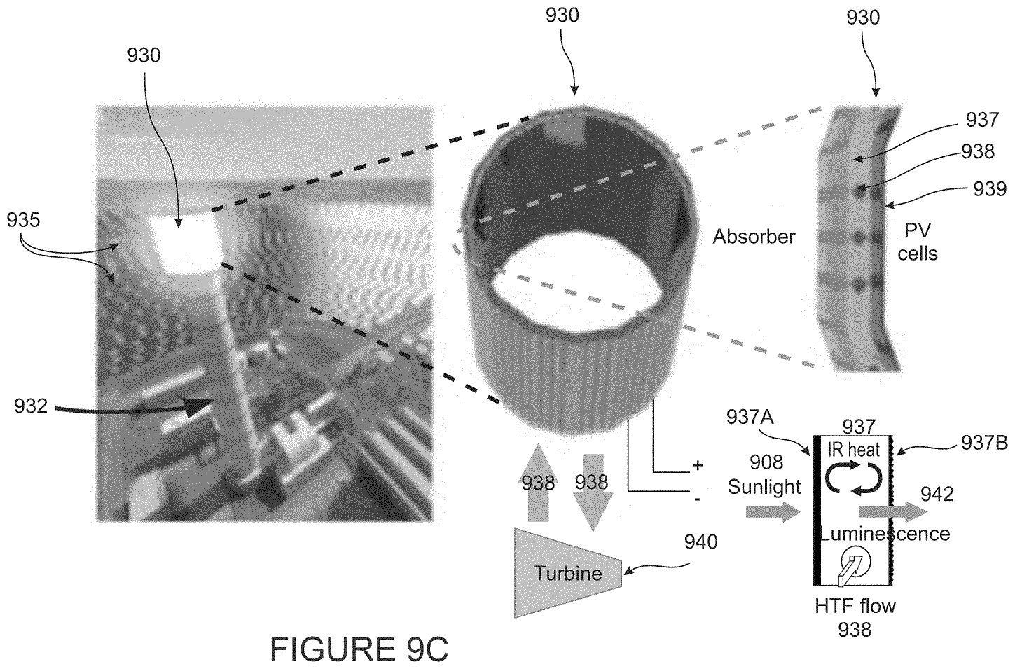

FIG. 7 shows an example embodiment with an optionally tilted water surface inside a pressure chamber 704. The tilted water surface indicates an example receiver which may be tilted down in a configuration of a mirror field concentrating solar radiation on a solar tower, where the receiver is at the top of the solar tower, as shown below in FIG. 9. The orientation of the water surface can be at other directions for example when such a receiver is placed at a focus of a single concentrator (parabolic dish), not on a solar tower.

In some embodiments a bulk of TEPL material 707 is optionally a porous material, potentially enabling steam bubbles to escape to a surface of the TEPL material 707.

In some embodiments the TEPL material 707 has structures of pillars or rods, and bubbles are formed on the surface of the pillars or rods and reach the surface of the water.

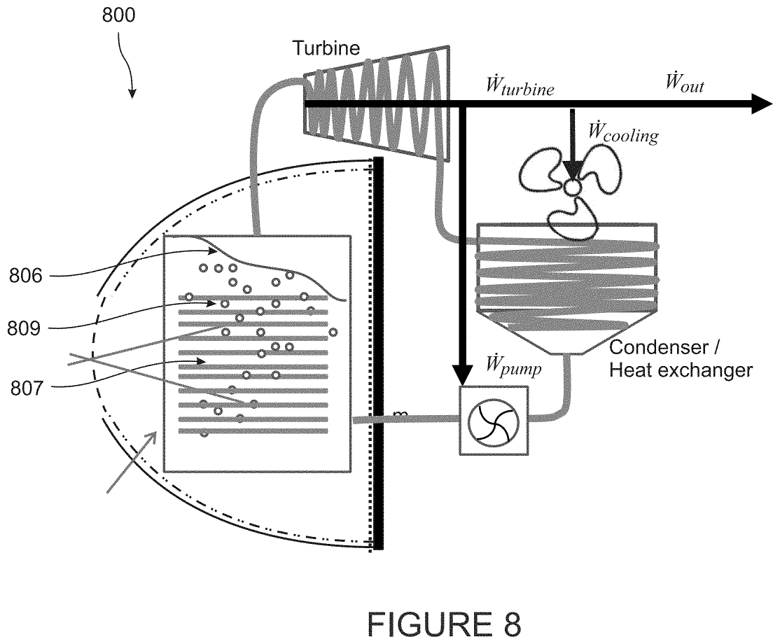

Reference is now made to FIG. 8, which is a simplified illustration of a system 800 for photovoltaic harvesting of energy and using liquid cooling to harvest additional energy according to an example embodiment of the invention.

FIG. 8 is a cross-sectional side view of the system 800.

FIG. 8 shows a system 800 similar to the system 700 of FIG. 7, with PL material 807 for absorbing radiation constructed as pillars or rods. Such a structure is potentially efficient in transferring heat from the PL material 907 to liquid 806.

FIG. 8 depicts an example embodiment with a rod-shaped TEPL material 807, which potentially allows bubbles 809 to reach an upper surface, and potentially reducing light scattering by a wave-guiding of solar radiation in the rods.

In some embodiments the steam turbine of FIGS. 7 and 8 is optionally operated by a liquid with a high evaporation temperature. Optionally the high evaporation temperature approximates or equals a TEPL operating temperature desired for emitting radiation for the PV cells.

In some embodiments the TEPL material 807 heats a gas such as argon, which evaporates a liquid through a heat exchanger. An example embodiment which includes an initial heating of gas potentially reduces pressure in the pressure chamber, thus potentially simplifying an energy conversion system.

Reference is now made to FIGS. 9A and 9B, which are simplified illustrations of a system for photovoltaic harvesting of energy according to an example embodiment of the invention.

FIGS. 9A and 9B show a system 901 for photovoltaic harvesting of energy on top of a tower 908, with mirrors 910 for directing sunlight 905 onto the system 901.

The system 901 optionally includes a chamber 904 and a system 902 for harvesting energy.

In some embodiments the system 902 may be, by way of some non-limiting examples, a system for photovoltaic harvesting of energy and using liquid cooling to harvest additional energy as illustrated in FIGS. 7 and 8.

In some embodiments the system 902 may be, by way of some non-limiting examples, a system for photovoltaic harvesting of energy as illustrated in FIGS. 2A-C, 3A-B, 4, 5A-C and 6.

FIGS. 9A and 9B show how an energy conversion system is optionally placed at the focus of a heliostat field.

In some embodiments a TEPL device is optionally integrated into a one-dimensional (1D) radiation concentration system such as one or more parabolic trough(s).

Reference is now made to FIG. 9C, which is a simplified illustration of a system for photovoltaic harvesting of energy according to an example embodiment of the invention.

FIG. 9C shows a system 930 for photovoltaic harvesting of energy on top of a tower 932, with mirrors 935 for directing sunlight onto the system 930.

The system 930 optionally includes a PL material 937 for absorbing sunlight, pipes 938 with Heat Transfer Fluid (HTF) for absorbing heat from the PL material 937, and PV cells 939 for absorbing radiation emitted by the PL material 937 and/or solar radiation.

In some embodiments, such as shown in the non-limiting example of FIG. 9C, the pipes 938 are optionally embedded in the PL material 937, or pass through cavities in the PL material 937.

FIG. 9C shows schematically that the pipes 938 are used to provide heated HTF to a turbine 940.

FIG. 9C shows schematically that sunlight 908 is absorbed by the PL material 937, and used to emit luminescent radiation 942 for PV cells 939 to produce electricity, as well as to provide heated HTF through the pipes 938 to the turbine 940.

In some embodiments the PL material 937 is optionally coated at a front surface 937A 937B and/or at a back surface by a layer of Indium Tin Oxide (ITO). ITO has strong absorption at wavelengths between 1 micron and 2 microns that enhances absorption of the Near-IR solar spectrum and converts it to heat. High reflectivity of the ITO at longer wavelengths reduces IR losses and optionally keeps the temperature high for heat engine (turbine) efficiency.

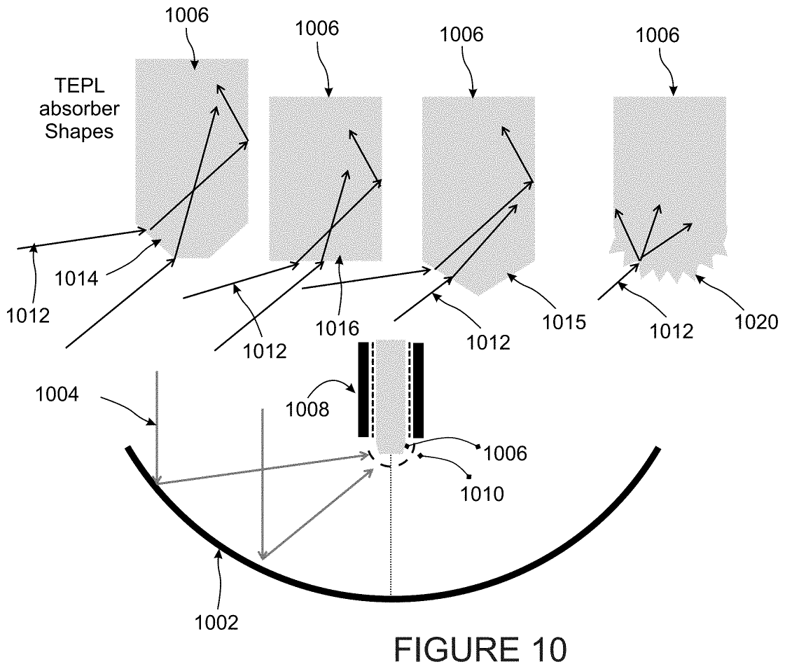

Reference is now made to FIG. 10, which is a simplified illustration of a system for photovoltaic harvesting of energy according to an example embodiment of the invention.

FIG. 10 shows a trough 1002 for concentrating sunlight 1004 onto a PL material 1006 surrounded by a PV material 1008, and optionally including a window 1010.

FIG. 10 shows a 1D parabolic trough 1002 which focuses light on an elongate shaped TEPL absorber 1006.

In some embodiments a head of the TEPL absorber 1006 potentially benefits from having a high index of refraction and optionally performs a secondary concentration, which guides light in the TEPL material. Such a configuration supports a longer optical path in the TEPL, and potentially increases the chances of an emitted photon to reach PV material and not escape back toward the parabolic mirror. In various embodiments the head of the TEPL is made in various shapes.

In some embodiments the head of the TEPL is shaped to allow the incoming radiation 1012 to be wave-guided by total internal reflection.

In some embodiments the head of the TEPL is optionally shaped in a shape such as a trapezoid 1014, a triangle 1015, a square 1016 and a hemispherical shape.

In some embodiments a multi-scattering and/or a diffusing surface is optionally achieved by a rough surface or a sharp edged surface 1020.

In some embodiments multi reflections acts so that the light does not reflect back to the mirror in the trough 1002.

In some embodiments the 1D concentration of a parabolic trough is optionally replaced with a spherical-shaped trough; potentially simplify construction and/or reducing costs. In a spherical shape the focus is potentially spread over a larger surface compared to a parabolic shape. This potentially reduces temperature gradients across the TEPL material.

In some embodiments a two-dimensional (2D) dish is optionally used to concentrate radiation. Adding circular symmetry to FIG. 10 describes a 2D parabolic or spherical dish. Light is concentrated on an optionally elongate-shaped TEPL material where the TEPL head optionally has shape of a cone, a chopped cone or a hemispherical dome.

In some embodiments the light is optionally wave-guided in the TEPL material.

In some embodiments PV material surrounds or partially surrounds the TEPL elongate shape.

In some embodiments the PV material 1008 optionally includes a tandem cell, such as, for example, a tandem Si/GaAs cell or a tandem GaInAs/GaAs cell.

In some embodiments a rough surface on the head of the TEPL material diffuses light and potentially reduces reflection losses.

Low Band Gap Thermally Enhanced Photoluminescence for Industrial Waste Heat Recovery

The industrial sector consumes one third of its total incoming energy and the remaining energy is discharged as wasted heat.

An aspect of the invention relates to using a Thermally Enhanced Photoluminescence (TEPL) device for harvesting industrial waste heat using photovoltaics.

A description is provided herein of an experimental demonstration of a low band gap Thermally Enhanced Photoluminescence device for harvesting industrial wasted heat using low band gap photovoltaics.

The experiments measure TEPL material radiation emission at increasing temperatures in a range which is included within a range of temperatures of waste heat. The results demonstrate a thermal blue shifting of emitted PL radiation energy at increasing temperatures above 50° C. The blue shift may be due to a Boltzmann distribution at lower temperatures and longer wavelength effectively enhancing the blue shifted emission through coupling of hot phonons with sub band gap photons.

From this observation, it is inferred that sub band-gap photons potentially extract up to 0.1 eV from the heat source. Further, this device can be implemented in harvesting industrial waste heat by coupling the device with a photon source and heat and the device harvests 20% of energy from the industrial waste heat below the photovoltaic band gap. Such a device can be extended for harvesting solar radiation between 1 μm and 2 μm, which is considered as wasted radiation, having energy less than a band gap of PV material commonly used in PV solar cells. Theoretical result shows that an ideal system can reach up to 28% efficiency for Ge solar cells. A low band gap TEPL device can operate at a range from lower temperature till 900 K, such a device has a potential of competing with thermo-electric power generation.

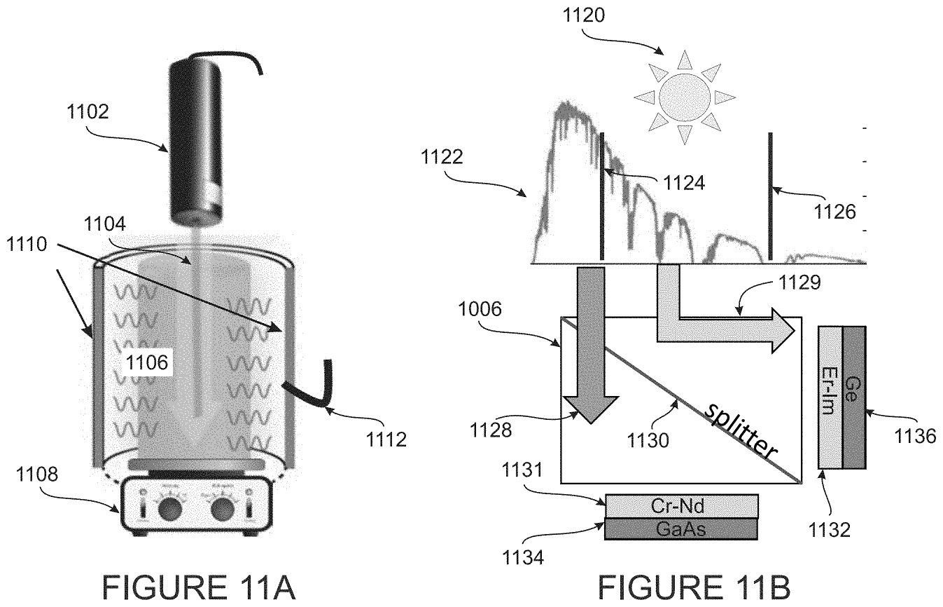

Reference is now made to FIGS. 11A and 11B, which are simplified illustrations of systems for harvesting waste heat or infra-red radiation according to example embodiments of the invention.

FIG. 11A shows a system which demonstrates harvesting PV electric energy from a laser providing radiation at wavelengths less energetic than would cause the PV material to emit electrons.

FIG. 11A shows a laser 1102 emitting a beam 1104 into TEPL material 1106. The TEPL material is heated by some source of heat 1108. The TEPL material 1106 emits radiation which is absorbed by PV material 1110, which produces electricity 1112.

In some embodiments the laser 1102 emits the beam 1104 at a wavelength which is not energetic enough to cause the PV material 1110 to produce electricity, and by virtue of the thermal enhancement, the TEPL material 1106 emits radiation energetic enough to be absorbed by the PV material 1110 to produce electricity 1112.

FIG. 11B shows a system which demonstrates harvesting PV electric energy from sunlight, including at wavelengths less energetic than would cause the PV material to emit electrons.

FIG. 11B shows a sun 1120 as a source of light. The light is illustrated by a graph 1122 showing a spectrum of the sunlight. The graph also shows two bars, a first bar 1124 at a shorter, more energetic wavelength, and a second bar 1126 at a longer, less-energetic wavelength. The two bars 1124 1126 represent edges of absorption band of two PV materials 1134 1136. Each one of the of two PV materials 1134 1136 emits electrons and produces electricity at wavelengths shorter than the edges of the absorption band associated with that material.

FIG. 11B demonstrates use of a beam-splitter 1130 to split incoming light into a shorter-wavelength more-energetic light 1128 and a longer-wavelength less-energetic light 1129.

In some embodiments the beam-splitter 1130 splits the incoming light at a wavelength of approximately 1100 nm.

In some embodiments, the more-energetic light 1128 includes approximately 73% of the energy of the sunlight, and the less-energetic light 1129 includes approximately 27% of the energy of the sunlight

In some embodiments the shorter-wavelength more-energetic light 1128 is optionally absorbed directly by a first PV material 1134 and emits electrons, producing electricity.

In some embodiments the shorter-wavelength more-energetic light 1128 is absorbed by a first PL material 1131, which emits PL radiation, which is absorbed by a first PV material 1134 which emits electrons, producing electricity.

In some embodiments the first PL material 1131 comprises Cr—Nd.

In some embodiments the first PV material 1134 comprises GaAs.

In some embodiments the longer-wavelength less-energetic light 1129 is absorbed by a second PL material 1133, which emits PL radiation, which is absorbed by a second PV material 1136.

In some embodiments the second PL material 1132 comprises Er—Tm.

In some embodiments the second PV material 1136 comprises InGaAs.

FIG. 11B depicts a TEPL energy device where in addition to solar wavelength shorter than 1100 nm, longer wavelength which are considered infrared (IR) radiation are absorbed by a low bandgap TEPL absorber and harvested by a low bandgap PV material.

A non-limiting example of PL materials that absorb at a wavelength range between 1 μm and 2 μm includes Erbium, Thulium.

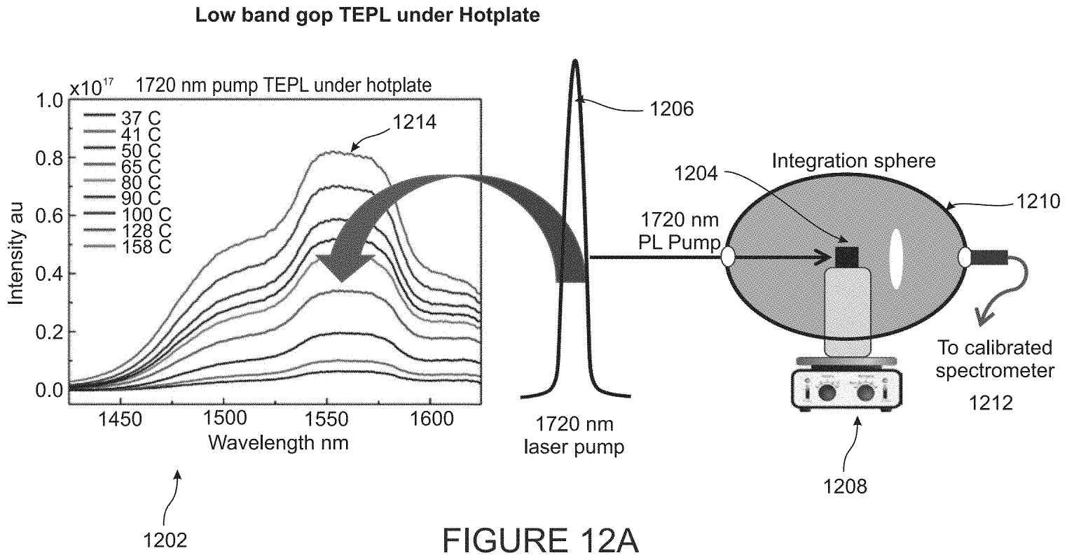

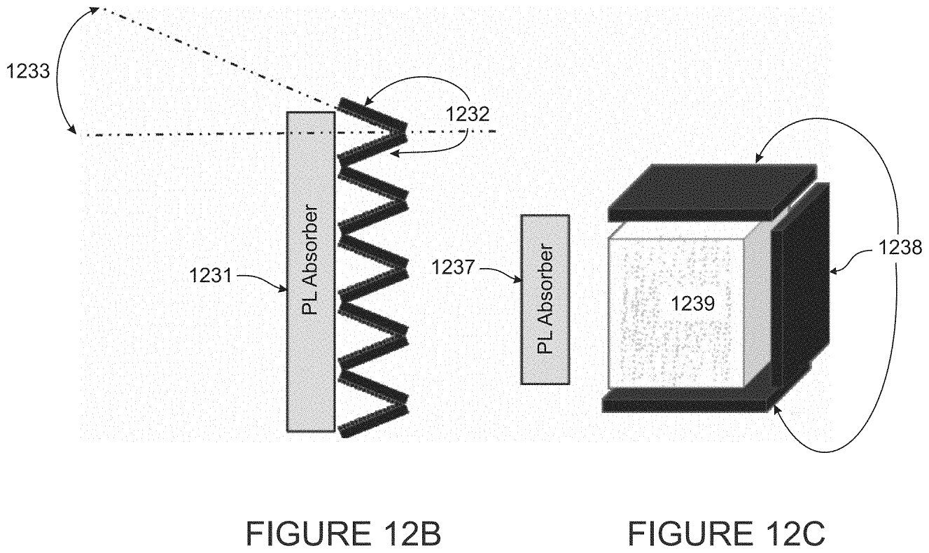

Reference is now made to FIG. 12A, which is a simplified illustration of a PL material emitting radiation according to an example embodiment of the invention.

FIG. 12A shows a graph 1202 of ErTm 1204 PL material emission when the ErTm 1204 PL material is excited by a 1720 nm laser 1206 and heated by a hot plate 1208.

Radiation emitted by the ErTm 1204 PL material is optionally collected by an integration sphere 1210 and sent to a spectrometer 1212 to produce the graph 1202. The radiation from the 1720 nm laser 1206, after re-emission by the ErTm 1204 PL material, produces a peak 1214 in the re-emitted radiation at a shorter, more-energetic wavelength of approximately 1550 nm.

As can be seen in the graph 1202, the heated PL material converts the 1720 nm emission into 1550 nm emission accessible for Ge or InGaAs solar cells. This is an example demonstration of harvesting wasted heat.

One challenge in solar energy today is not necessarily electricity generation price, which is already under fossil fuel price for photovoltaics (PVs) (<0.04 $/kWh), but rather the ability to store utility-scale electricity at competitive prices. To date, a conventional method for efficiently and reliably storing such energy is Thermal Energy Storage (TES) combined with Concentrated Solar Power (CSP). Despite its past decline, demands for CSP are increasing, which require alternative dispatchable energy generation. However, the combined production and storage price for this technology is still much higher than PVs (0.06 $/kWh-0.12 $/kWh).

Thermodynamically PVs and CSP use two different energy transport mechanisms. PVs uses free energy captured in an electron-hole pair generated by a quantum process of photon absorption, while CSP uses a generation of phonons in a process of thermalization, where free energy is lost. Even though these processes may be considered as independent, the generation of electron hole pairs typically does not occur spontaneously without a loss of free energy in a thermalization process. If PVs efficiency is made to tolerate high temperatures (for example 600C), it can be beneficiary to concentrate solar radiation onto PVs, harvesting the available free energy, while in parallel harvesting the high quality thermal energy through CSP. This cannot be done with conventional PV systems as their efficiency decreases sharply with temperature. But what is not done solely with electrons can be done with photons.

An aspect of some embodiments relates to focusing solar radiation onto a photoluminescent (PL) absorber, experimentally demonstrating 90% quantum efficiency while operating at 600° C. In some embodiments the PL material optionally has a narrow line shape that matches a band-edge absorption of Si and GaAs PVs, which offers CPV (concentrated photo-voltaic) at 40% efficiency with minimal heating. Together with a 35% turbine efficiency at 600° C. some embodiments offer a 50% enhancement in the efficiency of CSP, with electricity price down below 0.04 $/kWh, opening a door for on-demand electricity at silicon prices.

One challenge in solar energy today is not necessarily the cost of photovoltaic (PV) electricity generation, already competing with fossil fuel prices, but utility-scale energy storage costs. Some low cost thermal energy storage (TES) exists, and typically relies on expensive concentrated solar power (CSP). A technology able to unify PV conversion with TES may usher in an era of efficient base-load renewable power plants.

An aspect of some embodiments is named herein luminescence solar power (LSP), where a photoluminescent (PL) absorber optionally spatially separates heat and free-energy, allowing unification of PV conversion with TES.

An example material for the unification is, by way of a non-limiting example, rare-earth materials, optionally doped in YAG crystals. Such material has experimentally demonstrated tailored luminescence with EQE (external quantum efficiency) of up to 90% and at a temperature of 600° C. At such temperatures practical LSP efficiency may reach 32%, exceeding conventional side-by-side PV/CSP efficiency, and leading to a potential reduction of solar energy storage levelized cost of electricity (LCOE) to below 3 ¢/kWh.

Concentrated solar power (CSP) denotes herein a technology wherein a thermal absorber is heated by concentrated sunlight, thus enabling thermal energy storage (TES), such technology is expected to reach practical conversion efficiencies of up to 22% at peak hours by 2020. CSP electricity generation is expensive in terms of levelized cost of electricity (LCOE), roughly 6 ¢/kWh nowadays, compared to possible 2 ¢/kWh for Si based photo-voltaics (PVs). However, utility scale TES has kept this technology alive, due to its low cost of 1 ¢/kWh4. Projection of storage in solar energy prices reduced by half by 2030 estimates that half the US energy production will come from solar. PV with battery-based storage at a utility scale is far from that goal, placing CSP as the prime candidate to turn this vision into reality.

An aspect of some embodiments boosts overall plant efficiency, without sacrificing TES capabilities. The potential of the thermodynamic concept can be explained by the following example. Take a PV solar cell that can operate efficiently under concentrated sunlight and at elevated temperatures of up to 600° C. The PV solar cell enables harvesting electrical energy in the PV as conventionally done, but parallel thermalization-induced heat can be stored and later harvested, by way of a non-limiting example by using a steam power generator, for example a steam power generator with an efficiency exceeding 40%. This is challenging if attempted by using conventional PVs since their efficiency drops as the temperature rises. However, what cannot be done with conventional electron technology is possible with photoluminescence (PL).

The PL process involves absorption of energetic photons, followed by thermalization and emission of low energy red-shifted photons. The emission efficiency—i.e., the external quantum efficiency (EQE)—does not necessarily depend on the material temperature. When the emission is tuned to fit a PV cell's band-edge, the PL absorber retains a photon's extra heat, while the PV generates free energy with minimal wasted heat. This aspect, namely luminescent solar power (LSP), enables spatial separation of heat from free energy. Other hybrid concentrated photo-voltaic/thermal (CPV/T), such as PV heat extraction and spectral splitting, fall short by sacrificing heat utilization for PV efficiency or vice-versa, where with LSP potentially each solar-photon contributes both to the TES and the PV conversion.

Dilution of Photonic Flux

Dilution of photonic flux potentially enables using low cost PV cells and/or materials in a concentrated solar power (CSP) system: It may be cost effective to use off the shelf solar cells that are designed for low concentration. For example Si solar cells made for concentrations of 100 suns, 50 suns or even 10 suns. Also multi-junction solar cells may be designed for 10, 50, 100, 300, 500, 1000 suns, or more.

In some embodiments, for example when concentrated light emitted from a PL absorber exceeds the specifications of a PV cell, a dilution geometry may be applied. In such a concept the PVs trajectory is made at angle with respect to the emission from the PL absorber. The angle reduces the geometric factor of the PV with respect to the absorber thereby reducing the photonic flux impinging on the PV.

Reference is now made to FIG. 12B, which is a simplified illustration of an example configuration of PL material and PV material for dilution of photonic flux according to an example embodiments of the invention.

FIG. 12B shows PL material 1231 facing PV material 1232, with surfaces of the PV material 1232 which face the PL material configured at an angle 1233 to the plane of the PL material 1231.

FIG. 12B shows an optional geometry of triangles.

Another method for diluting photon flux at a PV is by using diffusers or scatterers.

Reference is now made to FIG. 12C, which is a simplified illustration of an example configuration of PL material and PV material for dilution of photonic flux according to an example embodiments of the invention.

FIG. 12C shows PL material 1237 facing a volume 1239 with PV material 1238 facing into the volume 1239.

FIG. 12C shows a non-limiting example where all the walls of the volume 1239, except a wall facing the PL material 1237, are PV material 1238 or PV cells 1238.

In some embodiments the volume 1239 contains optical scattering material, which potentially reduces photonic flux at the PV material by scattering radiation to the walls of the volume 1239.

FIG. 12C shows an example where the PV material is shaped as a box containing optical scattering material with one side, the side facing the PL material 1237, open to the radiation from the PL material 1237.

In some embodiments a photonic flux dilution factor is approximately the area of the PV material 1238 divided by the PL material 1237 absorber area.

Other optional geometries may include pyramid or even cylindrical shapes for thin PVs that can be curved.

In some embodiments the area of the PV material is 5, 10, 50, 100 larger than the area of emission from the PL absorber, thereby allowing for low-concentration PVs to be coupled to a PL absorber illuminated by high concentration solar radiation.

In some embodiments energy harvesting system using photonic flux dilution as described herein potentially enable solar energy harvesting systems to work at solar concentration of 10, 50, 70, 100, 200, 500 suns.

Enhancing Absorption of Near IR Solar Radiation

In some embodiments a PL absorber is designed to have high PL efficiency (quantum efficiency). For this the PL absorber is optionally designed to be transparent at a Near-IR part of the solar spectrum, in which approximately 30% of the solar energy resides.

For potentially extracting more heat energy from the sun and potentially to convert the Near-IR spectrum to heat, an additional coating on the PL absorber is optionally added, or dopants are optionally added inside the PL absorber to absorb the Near-IR spectrum. These additional materials are optionally transparent at the absorption and at the emission spectrum of the PL absorber.

By way of some non-limiting examples a PL absorber is made of Quartz, or SPINEL (MgAl₂O₄), or ALON (Aluminum Oxynitride), or YAG (Yttrium Aluminum Garnet), or Sapphire.

In some embodiments these materials are optionally doped with PL emitters, optionally durable at high temperatures, such as Cr, Ce, Yb, Nd, Manganese, Li2MnO3. Such a composition may have strong absorption at the visible spectrum up to the emission of Nd, at about 1 micron wavelength. The material is optionally transparent between 1 micron and 5 microns, leaving the Near-IR part of the spectrum un-absorbed.

In some embodiments ITO coating is added onto the PL absorber, to absorb the Near-IR solar spectrum, and converts it to heat.

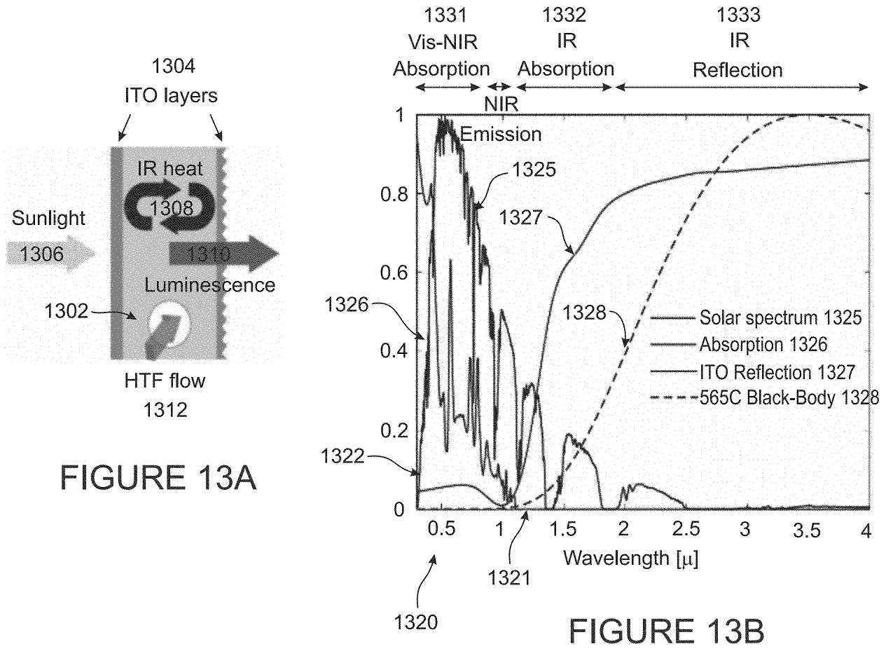

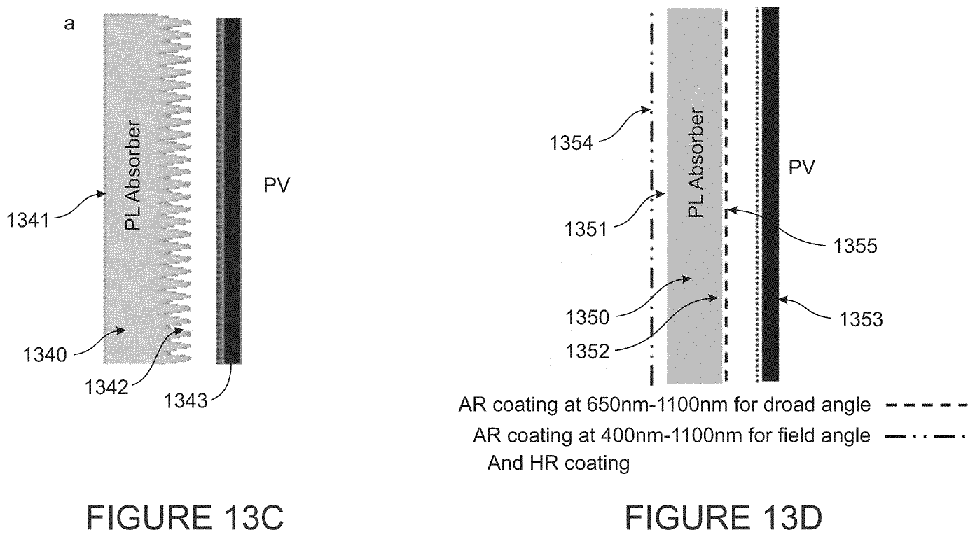

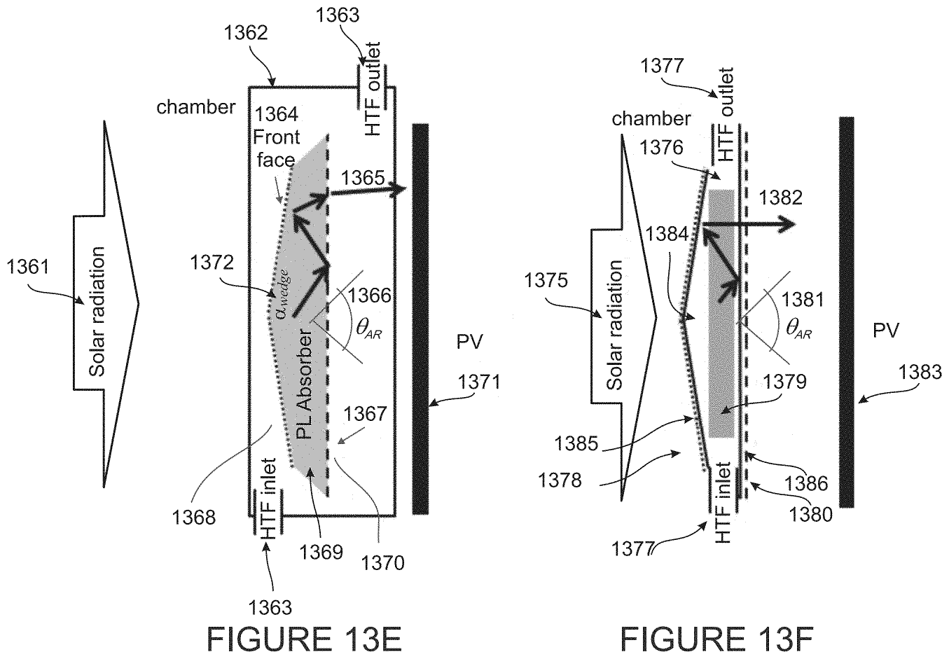

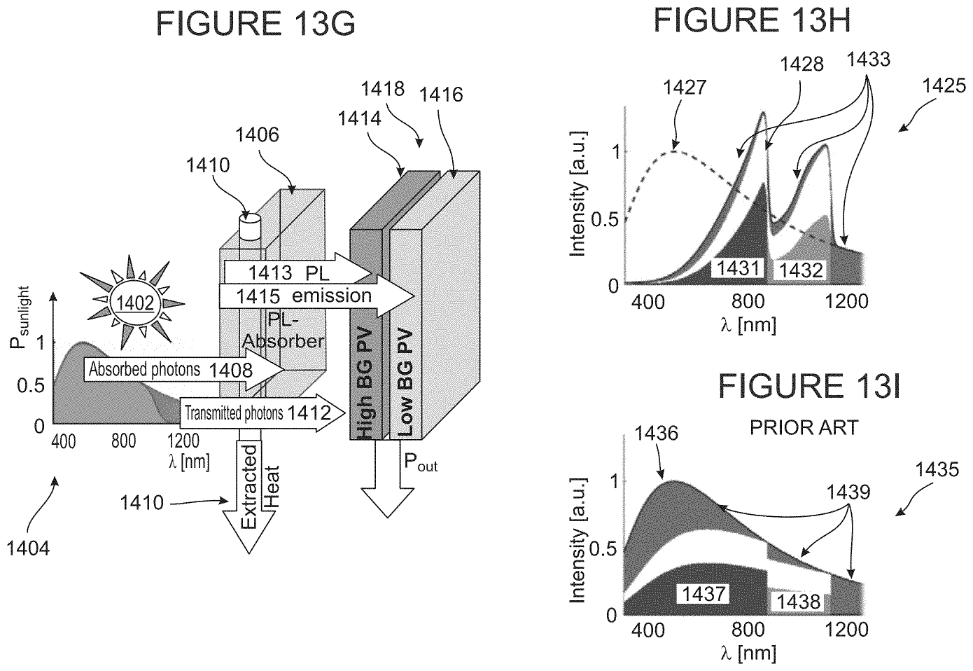

Reference is now made to FIGS. 13A and 13B, which are simplified illustrations of using properties of an Indium Tin Oxide (ITO) layer in example embodiments of the invention.

FIG. 13A shows a schematic illustration of a PL 1302 absorber configured with ITO coatings 1304 on a front and/or back surface, relative to a direction of impinging sunlight 1306.

In some embodiments the PL 1302 absorber absorbs sunlight 1306, heats up 1308, and the heat is mostly reflected by the ITO coatings 1304. The PL 1302 absorber absorbs sunlight 1306, heats up, and emits luminescent radiation 1310, optionally toward a PV cell (not shown).

FIG. 13A—depicts a cross section of the PL absorber 1302. With the ITO coating 1304 and optional high temperature fluid (HTF) 1312 to carry heat to an optional heat engine for energy production. The ITO coating 1304 potentially blocks IR emission, potentially reducing heating of an adjacent PV.

FIG. 13B shows a graph 1320 with four lines showing spectral properties relevant to example embodiments of the invention.

The graph 1320 has an X-axis 1321 showing wavelength in microns, and a Y-axis 1322 showing relative values for the four lines.

The graph 1320 also has additional markings 1331 1332 1333 along a top of the graph 1320, showing wavelength ranges: a Visible-NIR range 1331; an IR range 1332; and a longer-wavelength IR range 1333.

The graph 13B shows the following lines:

a first line 1325 showing relative intensity of impinging solar radiation;

a second line 1326 showing relative absorption of a PL absorber such as the PL absorber 1302 of FIG. 13A;

a third line 1327 showing relative values of ITO reflection; and

a fourth line 1328 showing relative black-body radiation at a temperature of 525 degrees Celsius.

The first line 1325 and the second line 1326 show that the PL material absorbs radiation in a bandwidth corresponding to the solar spectrum.

The third line 1327 and the fourth line 1328 show that the ITO reflects radiation in a bandwidth corresponding to emission expected from hot material. The example temperature of 565 degrees Celsius represent a relatively hot temperature, such as can be found in example embodiments of the invention, and are not typically found in PV cells, for example.

FIG. 13B shows ITO optical properties, transparent at the Visible-NIR range 1331 where the PL absorber absorbs and emits. The ITO has strong absorption between 1 micron and 2 microns that enhance absorption of Near-IR spectrum and converts the radiation to heat. High reflectivity of the ITO at longer wavelengths reduces IR losses and keeps the temperature hot, potentially for heat engine (turbine) efficiency.

In some embodiments functionality of the ITO coating can also be achieved by placing an additional window, optionally doped or coated with absorbing materials at the Near-IR spectrum.

In some embodiments HTF delivers heat from such a window to an optional heat engine.

In some embodiments a coating material having a spectrally-selective solar absorber is optionally configured to transfer incident solar radiation and to reflect heat radiation at wavelengths longer than about 2 microns.

In some embodiments a material with an absorption spectrum absorbing between 1 micron and 1.5 microns is optionally added to energy harvesting apparatus according to an example embodiment of the invention, absorbs radiation spectrum from the sun, and transfer heat to HTF.

In some embodiments an ITO layer is optionally used for absorbing solar spectrum and transferring heat to HTF.

Low Effective Index.

In some embodiments photoluminescence from a PL absorber is configured to reach the PV. In order to enhance radiation coupling, wave-guiding of radiation impinging upon the PL absorber is optionally reduced.

For a planar bulk waveguide, such as a slab-shape PL absorber, having an index of refraction of 1.5, radiation coupling out from a face of the bulk to air is about 12.5%, while the rest, approximately 75% of the light, is kept within the bulk by total internal reflection and another 12.5% is radiates toward the PV.

For a planar bulk index of refraction of 1.8, about 84% of the emitted light remains in a waveguide shaped planar bulk.

In some embodiments a porous layer structure is used, where a large part of the volume of the planar bulk is composed of air induces an effective volume average of the refractive index near the value of the refractive index of air, n=1.

In some embodiments a gradual reduction in an effective refractive index from bulk to air potentially reduces back reflection of light into the PL absorber.

For large absorber bulk thickness it is possible to cut and/or polish a back side of the absorber in a prism shape. Analyzing such a structure shows that most of the light is not reflected.

Reference is now made to FIG. 13C, which is a simplified illustration of a shape of a PL absorber according to an example embodiment of the invention.

FIG. 13C shows a PL absorber 1340 with a flat front face 1341, for facing incident radiation, and a specially configured back face 1342 for facing a PV cell 1343.

The back face 1342 shown in FIG. 13C is shaped as multiple prisms with their bases toward a bulk of the PL material and their points toward the PV cell.

FIG. 13C shows a prism structure of the PL absorber.

In some embodiments the prism shape of the back face 1342 is used to enhance directional emission toward a PV cell.

In some embodiments unpolished prisms are used. In such a case, a portion of light reflected back from the prism's external face corresponds to a view factor of the base, which can be engineered to be smaller than 0.2 and even smaller than 0.1.

In some embodiments prisms with shape ratio of 5 between an external face length and a base the view factor of the base is 1:5, or 20%. When an external face is unpolished only 20% of the light returns to the bulk. By using an effective low index and a prism shape a coupling efficiency of radiation reaches 87.5% for an index of refraction of 1.5 and 92% for an index of refraction of 1.8.

In some embodiments a PL-absorber has an effective low refractive index in order to reduce wave-guiding of the PL emission.

In some embodiments an AR coating is used to reduce internal reflection significantly.

In some embodiments an AR coating used to reduce internal reflection is said to produce an effective low refractive index, even an effective index of refraction as low as 1.

Reference is now made to FIG. 13D, which is a simplified illustration of a shape of a PL absorber according to an example embodiment of the invention.

FIG. 13D shows a PL absorber 1350 with a flat front face 1351, for facing incident radiation, and a flat back face 1352 for facing a PV cell 1353.

In some embodiments the PL-absorber 1350 optionally includes an AR/HR coating 1354 at the front face 1351 and/or an AR/HR coating 1355 at the back face 1352 that potentially enhances a portion of PL emission which reaches the PV cell 1353.

In some embodiments the front AR coating 1354 is designed for transmitting light at wavelengths between 400 nm and 1100 nm arriving at angles smaller than field angles. In some embodiments the front AR coating 1354 is designed for being highly reflective for the PL-absorber 1350 emission at wavelengths between 650 nm and 1100 nm at other angles.

In some embodiments the AR coating is optionally designed for wavelengths between 400 nm and 1500 nm, or even 1700 nm, in order to let in IR radiation to be converted to heat at the PL absorber 1350.

In some embodiments the back face 1352 has an AR coating 1355 being anti-reflective at an entire spectrum of light with photon energies above the bandgap of the PV 1353, and at as broad an angle as possible, in order to allow maximal flux of photons to reach the PV 1353 and generate electricity.

Reference is now made to FIG. 13E, which is a simplified illustration of a wedge shaped PL absorber according to an example embodiment of the invention.

FIG. 13E is intended to demonstrate a configuration of a PL absorber 1369 which reduces internal reflection within the PL absorber 1369 enabling radiation emitted by the PL absorber 1369 to exit a bulk of the PL absorber toward a PV cell 1371.

FIG. 13E shows solar radiation 1361 entering an optional chamber 1362, optionally containing HTF, within which the PL absorber 1369 is placed. A front face 1364 of the PL absorber 1369 is shaped as a wedge with a head angle α_{wedge} 1372. Light 1365 emitted from a back face 1367 of the PL absorber 1369 continues toward the PV cell 1371.

In some embodiments the PL absorber 1369 is optionally placed in a chamber 1362. In some embodiments the chamber 1362 optionally contains heat transfer fluid (HTF). In some embodiments the chamber 1362 optionally includes HTF inlet(s) 1363 and outlet(s) 1363, for optionally enabling flow of the HTF through the chamber 1362.

In some embodiments the back face 1367 of the PL absorber 1369 is optionally coated with an Anti-Reflective (AR) coating 1370, anti-reflective at wavelengths of emission of the PL absorber 1369. In some embodiments the back face 1367 AR coating is designed for wavelengths between 650 nm and a wavelength corresponding to a band-gap of the PV material, at angles of incidence of θ>θ_{AR}, where θ_{AR} is an angle 1366, measured inside the PL material, at which light emitted from the PL absorber 1369 exits and is not internally reflected.

In some embodiments the front face 1364 of the PL absorber 1369 is optionally coated with a highly reflective (HR) coating 1368, highly reflective at wavelengths of emission of the PL absorber 1369. In some embodiments the front face 1364 HR coating is designed for wavelengths between 750 nm and a wavelength corresponding to a band-gap of the PV material, at angles of incidence of θ>θ_{field}.

In some embodiments the front face 1364 of the PL absorber 1369 is optionally coated with an AR coating 1368 at wavelengths which do not let through wavelengths of emission of the PL absorber 1369 and do let through solar energy. In some embodiments the front face 1364 AR coating is designed for wavelengths between 400 nm and 1100 nm, at angles of incidence of θ<θ_{field}.

FIG. 13E shows a conical or prism or wedge shaped PL absorber 1369 optionally having a head angle of α_{wedge} 1372 and a front-face 1364 AR coating 1368 designed to minimize reflection losses of radiation coming from the solar field and maximize reflection of PL emission.

In the example embodiment of FIG. 13E optionally a single junction Si solar cell is used to harvest the PL absorber 1369 emission. For this the PL absorber may absorb radiation between 400 nm and 750 nm, leaving the longer wavelength solar photons with wavelengths between 750 nm and 1100 nm to directly reach a Si PV 1371.

In some embodiments, for example such as described above, the optional front face 1364 AR coating 1368 is preferably designed for 400 nm-1100 nm wavelengths at solar field angles θ<θ_{field}. At larger angles the coating is preferably HR for the PL emission between 750 nm and 1100 nm.

In some embodiments the back face 1367 AR coating 1370 is optionally between 650 nm-1100 nm and at broad angles θ_{AR}. Stray PL emission and direct solar emission that are at angles larger than θ_{AR} are reflected back to the front face 1364 of the PL absorber 1369 and are reflected at an additional angle (180−α_{wedge}). As a result, an angle of stray light at a 2nd encounter with the back face 1367 is at an angle that matches the AR coating and the stray light exits the PL absorber 1369 and reaches the PV.

It is noted that when (180−α_{wedge}) is equal to θ_{AR} then even radiation at an angle of 2×θ_{AR} will eventually exit.

In some embodiments such a function of the head angle α_{wedge} is optionally replaced with an ergodic geometry or a diffused surface which scrambles an incident angle of stray light propagating in the PL absorber 1369 media, which eventually results in stray light reaching the PV.

Reference is now made to FIG. 13F, which is a simplified illustration of a wedge shaped cavity containing a PL absorber according to an example embodiment of the invention.

FIG. 13F is intended to demonstrate another configuration of a PL absorber 1379 which reduces internal reflection within a chamber 1376, the chamber 1376 enabling radiation emitted by the PL absorber 1379 to exit the chamber 1376 toward a PV cell 1383.

FIG. 13F shows solar radiation 1375 entering a chamber 1376 within which the PL absorber 1379 is placed. A front face 1378 of the chamber 1376 is shaped as a wedge with a head angle α_{wedge} 1384. Light 1382 emitted from a back face 1380 of the chamber 1376 continues toward the PV cell 1383.

In some embodiments the PL absorber 1379 is optionally placed in a chamber 1376. In some embodiments the chamber 1376 optionally contains heat transfer fluid (HTF). In some embodiments the chamber 1376 optionally includes HTF inlet(s) 1377 and outlet(s) 1377, for optionally enabling flow of the HTF through the chamber 1376.

In some embodiments the PL absorber 1379 optionally has a refractive index that matches the refractive index of the HTF.

In some embodiments the back face 1380 of the chamber 1376 is optionally coated with an Anti-Reflective (AR) coating 1386, anti-reflective at wavelengths of emission of the PL absorber 1369. In some embodiments the back face AR coating 1386 is designed for wavelengths between 750 nm and a wavelength corresponding to a band-gap of the PV material, at angles of incidence of θ>θ_{AR}, where θ_{AR} is a head angle 1381 at which light emitted from the chamber 1376 exits and is not internally reflected.

In some embodiments the front face 1378 of the chamber 1376 is optionally coated with a highly reflective (HR) coating 1385, highly reflective at wavelengths of emission of the PL absorber 1369. In some embodiments the front face HR coating 1385 is designed for wavelengths between 750 nm and a wavelength corresponding to a band-gap of the PV material, at angles of incidence of θ>θ_{field}.

In some embodiments the front face 1378 of the chamber 1376 is optionally coated with an AR coating 1385 at wavelengths which do not let through wavelengths of emission of the PL absorber 1369 and do let through solar energy. In some embodiments the front face AR coating 1385 is designed for wavelengths between 400 nm and 1100 nm, at angles of incidence of θ<θ_{field}.

In some embodiments various AR coatings can be placed on the chamber 1376, optionally using an index matching fluid as a Heat Transfer Fluid (HTF).

In some embodiments front and/or back dielectric coatings can be placed on additional front and/or back external windows. Such a configuration can potentially simplify fabrication of the coating, and may potentially lower heat reaching the coating, potentially enabling use of coating able to withstand lower temperatures.

Hydrogen Production at High Temperatures

In recent years it was demonstrated that hydrogen production can be more efficient at high temperatures, and CSP was offered as a mean for generating these high temperatures. See for example an article by A. Houaijiaa, S. Breuera, D. Thomeya, C. Brosiga, J.-P. Säcka, M. Roeba and C. Sattlera titled “Solar hydrogen by high-temperature electrolysis: Flowsheeting and experimental analysis of a tube-type receiver concept for superheated steam production”, published in Energy Procedia 49, 1960, (2014).

A concept of combining CSP & CPV in a TEPL device potentially enables supplying both heat and electricity for hydrogen generation. It is estimated that 38% Hydrogen to heat efficiency can be reached.

Front Heat Transfer Fluid

The Beer-Lambert law of radiation absorption implies that a PL absorber is heated more at a front face, where solar radiation arrives, than at a back face, where the PL absorber faces the PV.

In some embodiments it is beneficiary for HTF to flow on the hotter front face of the PL absorber. A potential benefit of configuring HTF to flow on the hotter front face of the PL absorber can be to balance a temperature difference across the PL absorber.

In some embodiments the HTF is configured to flow inside the PL-absorber but with an asymmetric distribution of the flow, to balance the asymmetric heat load and potentially maintain uniform temperature.

PL-Absorber as Nanoparticles Suspended in HTF:

Using a bulk PL absorber, and HTF that transfers heat to an engine such as a turbine requires complex engineering. Typically the HTF is designed to work at a uniform temperature, which is crucial to the achieving optimal efficiency.

In some embodiment a uniform HTF temperature is optionally achieved by using PL material made of nano-particles or micro particles suspended in the HTF. The small size of the particles potentially enables achieving a uniform temperature for the particle and for the HTF.

In some embodiments such particles are optionally made from a same bulk material as a bulk PL-absorber. By way of some non-limiting examples, the PL material made into nano- or micro-particles is optionally rare-earth doped SiO2 glass, YAG or some other matrix. A size of the particles is optionally determined by the heat conductivity of the PL particle material and a desire for a uniform temperature, which potentially leads to a size that can be as large as few centimeters and as small as sub-nanometer.

A non-limiting example for such materials is Cr co-doped Nd:Yb:YAG, which was described in an article titled “Luminescence properties of highly Cr co-doped Nd:YAG powder produced by sol-gel method”, by Kana Fujioka, Taku Saiki, Shinji Motokoshi, Yasushi Fujimoto, Hisanori Fujita, Masahiro Nakatsuka, published in the Journal of Luminescence, 30 (2010) 455-459. Such powder is optionally suspended in the HTF.

In some embodiments a transparent chamber for the HTF may have a prism structure and/or a coating with a low refractive index and/or an AR coating for efficient coupling of the PL radiation emission to a PV material and reducing emission back to the solar field.

Syngas:

In some embodiments synthetic gas (syngas) is optionally produced in a manner similar to water splitting.

A TEPL device or system which combines CSP & CPV in a same device or system potentially enables supplying both heat and electricity for electrolysis. In some embodiments the TEPL device or system supplies heat for thermo-chemically producing hydrogen. Among various thermo-chemical cycles tested for CSP-driven hydrogen production via water splitting (WS), thermo-chemical cycles based on redox-pair oxide systems are directly adaptable to carbon dioxide splitting (CDS) and/or combined CO₂/H₂O splitting for the production of CO or syngas, respectively. See description in an article by Christos Agrafiotis, Martin Roeb, and Christian Sattler titled “A review on solar thermal syngas production via redox pair-based water/carbon dioxide splitting thermochemical cycles”, published in Renewable and Sustainable Energy Reviews 42 (2015) 254-285.

To demonstrate a possibility of efficient LSP, materials with efficient solar absorption and PL emission at temperatures relevant for TES are chosen. In the following, we experimentally demonstrate the above and outline optical properties of the materials.

Example Device

Reference is now made to FIG. 13G, which is an illustration of radiation and heat flows in an example embodiment of the invention.

FIG. 13G illustrates a device as outlined above. Sunlight, optionally concentrated, shown as a sun symbol 1402 and as a graph 1404 showing an approximate spectrum of sunlight, is absorbed 1408 by a PL absorber 1406 that is heated by thermalization of the solar excitation. Heat transfer fluid (HTF) 1410 flows through the PL absorber 1406, leading the heat toward a heat engine power block (not shown in FIGS. 13G-I).

Radiation 1413 1415 emitted by the PL absorber is harvested by a multi-junction 1414 1416 PV cell 1418.

The sunlight optionally also penetrates 1412 through the PL absorber 1406, and the penetrating radiation 1412 is also harvested by the multi-junction 1414 1416 PV cell 1418.

Reference is now made to FIG. 13H, which is a graph illustrating spectral energy utilization of a system utilizing PL material and material according to an example embodiment of the invention.

FIG. 13H shows a graph 1425 having an X-axis of wavelength in nanometers and a Y-axis in arbitrary units showing spectral intensity.

The graph 1425 shows a first line 1427 corresponding to the solar spectrum shown in the graph 1404 of FIG. 13G; and a second line 1427 showing an emission spectrum of the PL material having two peaks, optionally each one of the peaks at a wavelength equal or approximately equal to bandgaps of the multi-junction PV cell.

The graph 1425 also shows several shaded areas:

a first shaded area 1431 corresponding to a portion of the spectrum which is potentially absorbed by a higher-band-gap PV material (reference 1414 in FIG. 13G);

a second shaded area 1432 corresponding to a portion of the spectrum which is potentially absorbed by a lower-band-gap PV material (reference 1416 in FIG. 13G); and

a third shaded area 1433 corresponding to a portion of the spectrum which is not used by the PV cell 1418 but is used for heating the HTF 1410.

For minimal heating of the dual-junction PV cell 1418, an optimal PL absorber 1406 material optionally has two emission peaks, optionally centered at wavelengths matching band-edges of each one of the two PV junctions, as shown in FIG. 13H.

Reference is now made to FIG. 13I, which is a graph illustrating spectral energy utilization of a PV material according to prior art.

FIG. 13I shows a graph 1435 having an X-axis of wavelength in nanometers and a Y-axis in arbitrary units showing spectral intensity.

The graph 1435 shows a first line 1436 corresponding to the solar spectrum shown in the graph 1404 of FIG. 13G.

The graph 1435 also shows several shaded areas:

a first shaded area 1437 corresponding to a portion of the spectrum which is potentially absorbed by a higher-band-gap PV material;

a second shaded area 1438 corresponding to a portion of the spectrum which is potentially absorbed by a lower-band-gap PV material; and

a third shaded area 1439 corresponding to a portion of the spectrum which is not used by the PV cell 1418 and heats the PV material of a multi-junction PV cell of the prior art.

In some embodiments, for minimal heating of the dual-junction PV cell 1418, a PL absorber 1406 material preferably has two emission peaks, each emission peak preferably centered at a wavelength matching a band-edge of each one of the two PV junctions, as shown in FIG. 13H.

In some embodiments much of the heat load induced by thermalization of energetic photons and solar infra-red light falls on the PL absorber material 1406, leaving just residual heating, corresponding to the third area 1433 of the graph 1425, at the PV 1418. Comparing the third area 1433 to a heat load under direct illumination of PV cells according to prior art, as shown by reference 1439 of FIG. 13I highlights that an effort spent on cooling the PV cells is potentially greatly reduced in embodiment of the invention. Non-ideal PVs, angular mismatch, radiative, Boltzmann and Carnot losses (all marked as white area in FIGS. 13H and 13I) also partially contribute to heat.

FIGS. 13G, 13H and 13I illustrate an example embodiment of luminescent solar power (LSP). FIG. 13G shows concentrated sunlight 1402 illuminating a PL absorber 1406. PL emission is coupled to PV cells 1418, optionally with different band-gaps 1414 1416, while residual heat is extracted for further use. FIG. 13H shows an emission intensity spectrum of the PL emitter, tailored to the PV cell band-gaps, and compared to the solar spectrum (dotted line 1427). The filled areas 1431 1432 1433 reflect the energy utilized by high band-gap (1431) and low band-gap (1432) PV cells, and the energy used for heating or lost on thermalization in these cells (1433). A white gap in graph 1425 corresponds to angular mismatch, radiative, Boltzmann and Carnot losses; most of the latter also contribute to heat in non-ideal solar cells, as shown in FIG. 13I.

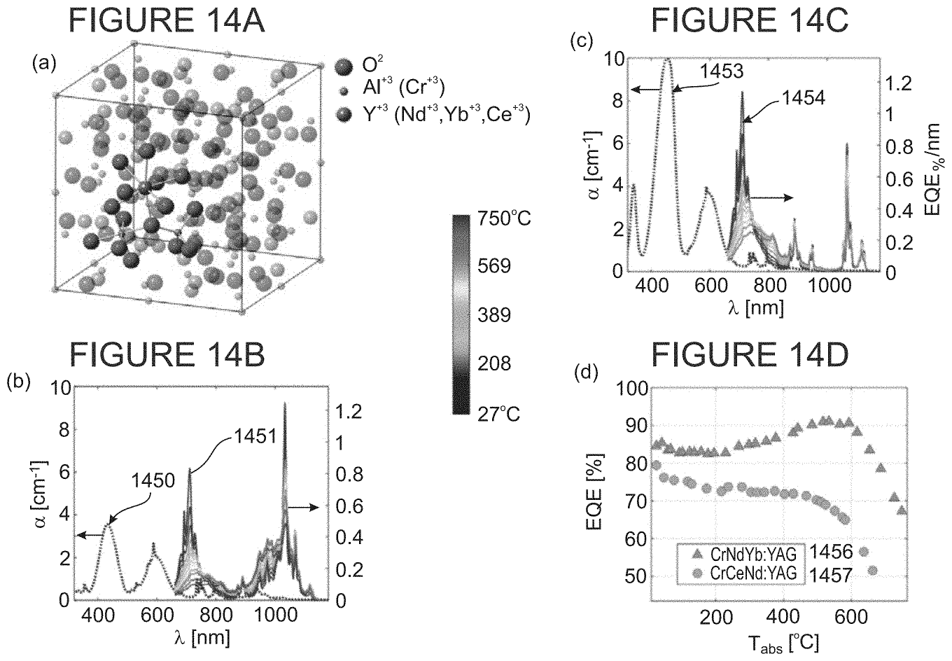

Reference is now made to FIGS. 14A-14D, which are simplified illustrations of properties of materials used in example embodiments of the invention.

FIG. 14A shows lattice structure and the position replacement of the different dopant ions of Yttrium aluminum garnet (YAG).

FIG. 14B shows room temperature absorption (dotted black line 1450) and temperature dependent emission spectra 1451 at room temperature and up to 750° C. under broad white light excitation for CrNdYb:YAG.

FIG. 14C shows room temperature absorption (dotted black line 1453) and temperature dependent emission spectra 1454 at room temperature and up to 750° C. under broad white light excitation for CrCeNd:YAG.

FIG. 14D shows EQE as a function of absorber temperature for CrNdYb:YAG (triangles 1456) and CrCeNd:YAG (circles 1457).

In some embodiments PV band-gap energies of 1.1 eV (for example typical Si or possibly InGaAsP cells) and 1.42 eV (for example GaAs cells) are targeted, with cutoff wavelengths of 1100 nm and 870 nm, respectively. A photo luminescent (PL) absorber-emitter for such a pair of band-gap energies optionally has a broad absorption of the solar spectrum, together with two major emission lines slightly shorter than the PV's cutoff wavelengths. For the 1.1 eV PV, the rare-earth (RE) elements neodymium (Nd3+) and ytterbium (Yb3+) with emission lines around 1 μm are an excellent fit. These materials also have high external quantum efficiency (EQE) when doped in transparent matrices such as yttrium aluminum garnet (YAG) (See FIG. 14A). A high EQE is retained at high temperatures, possibly due to isolation of the electronic transitions from the matrix phonons.

Materials used for broad absorption and sensitization of Nd3+, can be, by way of a non-limiting example, similar to material used for flash-pumped lasers, such as cerium (Ce3+) and chromium (Cr3+). Conveniently, introducing Cr3+ to a YAG crystal, replacing the Aluminum in the octahedral sites, introduces a strong emission line around 700 nm, roughly matching the band-edge of the 1.42 eV PV cell.

When sensitizing Nd3+ and Yb3+ with Cr3+ and Ce3+ benefits of quantum cutting are reaped, potentially allowing the emission of two photons with the absorption of one high energy photon. Furthermore, Nd3+ emission lines around 900 nm-1100 nm are blue-shifted at high temperatures by thermally enhanced PL, thereby becoming accessible to the 1.42 eV PV junction, benefiting a high voltage.

A variety of these dopant concentrations, using both ceramic and single crystal models, are now disclosed. Their spectral absorption and emission efficiency as a function of temperature are studied, and results are shown further below. A prominent comparison parameter is the EQE of the PL material. Of a variety of materials tested, two materials stood out. Both stand-out materials were (10×10×3 mm) YAG single crystal manufactured by SIOM, a first crystal doped with Cr3+:0.5 wt %, Nd3+:1 wt % and Yb3+:1 wt % (namely CrNdYb:YAG) and a second doped with Cr3+:0.5 wt %, Ce3+:0.5 wt % and Nd3+:1 wt % (namely CrCeNd:YAG). Both materials have broad absorption ranges up to 650 nm, and several narrow absorption lines in the near-IR (See FIGS. 14B and 14C, respectively). Accordingly, for a length of 1 cm, 38% in CrNdYb:YAG and 46% in CrCeNd:YAG would be absorbed from the total solar spectrum at wavelengths shorter than 1100 nm. As per the mechanical properties of YAG, its thermal stability and heat evacuation efficiency are proven by its use in high power laser disks.

Results

Room temperature EQEs of 84% and 79% were measured for CrNdYb:YAG and CrCeNd:YAG, respectively, under simulated solar excitation with a white light source in the range of 430-650 nm and by real solar excitation (see the Supplementary Information section).

A change in the absorption and emission spectra under constant excitation at elevated temperatures was also measured, to determine the EQE for each sample as a function of the PL absorber temperature (see FIG. 14D) (see the Supplementary Information section). The EQE not only retains its high values with temperature, but also rises to 90% in CrNdYb:YAG. This observation may possibly be explained by phonon-assisted cross-relaxation, increasing the Nd3+ and Yb3+ fluorescence lifetime owing to the presence of Cr3+ ions. In some embodiments the EQE may rise above 100%, possibly because of enhanced quantum cutting processes.

In some embodiments, upon reaching a certain temperature, a reduction in EQE takes place. For example, the reduction occurs at 600° C. for CrNdYb:YAG and at 500° C. for CrCeNd:YAG.

It is noted that the 700 nm peak in both samples appears to drop sharply as the temperature rises, possibly explained both by increased energy transfer to the acceptor ions and the reduction in Cr3+ emission efficiency.

In some embodiments an emission increase in the band of 750-1050 nm for CrNdYb:YAG and 750-900 nm for CrCeNd:YAG potentially counters the reduction, as demonstrated by thermally enhanced PL.

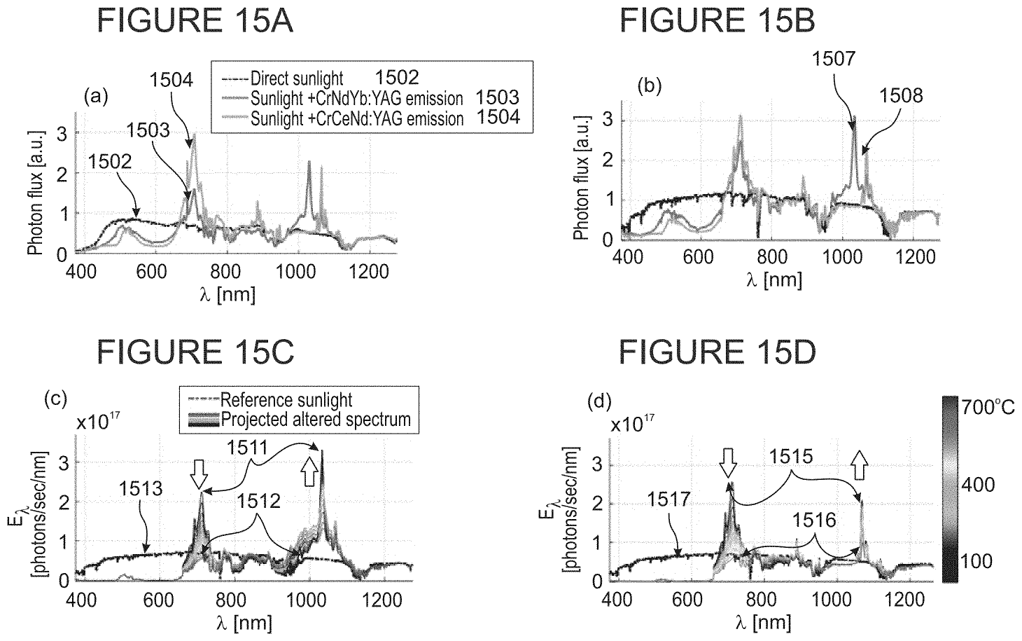

Reference is now made to FIGS. 15A-15D, which are spectral graphs illustrating solar spectra altered by passing through material used in embodiments of the invention.

FIG. 15A shows a measured solar spectrum (dotted line 1502) in an integration sphere compared to measured spectrum of sunlight exiting a 1 cm-long CrNdYb:YAG sample (line 1503) and a CrCeNd:YAG sample (line 1504).

FIG. 15B shows simulated altered spectra of CrNdYb:YAG and CrCeNd:YAG (lines 1507 and 1508 respectively) samples when excited by AM1.5 direct and circumsolar sunlight taken from NREL and using parameters matching the conditions in FIG. 15A.

FIG. 15C shows expected altered spectra of CrNdYb:YAG under full absorption conditions and different material temperatures (line 1511 at room temperature, up to line 1512 at 700 degrees Celsius), compared to direct illumination of 500 suns (dotted black line 1513).

FIG. 15D shows expected altered spectra of CrCeNd:YAG under full absorption conditions and different material temperatures (line 1517 at room temperature, up to line 1518 at 700 degrees Celsius), compared to direct illumination of 500 suns (dotted black line 1518).

A PV cell placed in an LSP device is optionally illuminated by both emission of the PL absorber and a sunlight portion transmitted by the material. In the example embodiment described above the crystal is mostly transparent for photons at wavelength longer than 650 nm, which are matched to the PV's band edge. Illustrating a spectrum altered by transmission through PL material, FIG. 15A shows a measured spectrum under real sunlight excitation after 1 cm propagation distance through the PL absorber at room temperature (see the Supplementary Information section). Two distinct peaks of the PL material at 700 nm and 1050 nm are evident, more than four-fold greater than the intensity of the reference solar spectrum at these wavelengths, as measured without a crystal (dashed line 1502). A similar spectrum (see FIG. 15B) is obtained by plotting a standard NREL solar spectrum transformed by measured absorption and re-emission (FIGS. 14A and 14B) calculated for a 1 cm-long sample. The similarity between FIGS. 15A and 15B potentially enables extrapolating the spectrum from the EQE measurements at elevated temperatures.

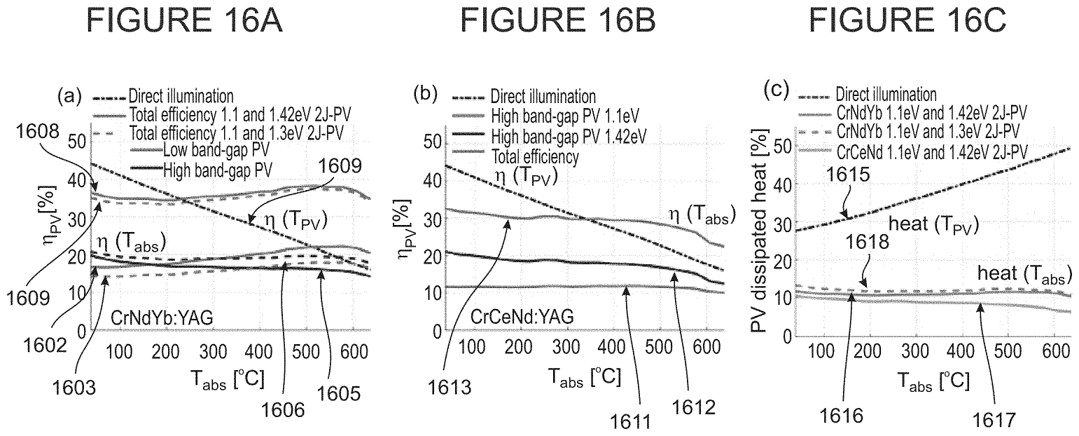

Using the above-described technique, operating conditions of an LSP device are developed. Transmission and emission spectra under excitation of 500 suns, through a 4 cm-long CrNdYb:YAG sample (FIG. 15C) and a 3 cm-long CrCeNd:YAG sample (FIG. 15D) at different absorber temperatures, are calculated (see the Supplementary Information section). Using the calculated spectra and a detailed balance calculation, an output efficiency of an ideal dual-junction PV cell is optionally calculated (FIGS. 16A and 16B) and total dissipated heat falling on the cells as a result of thermalization and series resistance (FIG. 16C) (see the Supplementary Information section).

Reference is now made to FIGS. 16A, 16B and 16C which are graphs showing modeled efficiency of some devices according to example embodiments of the invention.

FIG. 16A shows modeled device efficiency under excitation of 500 suns through a 4 cm-long CrNdYb:YAG sample: an expected output efficiency of dual-junction PV cell comprising an ideal 1.1 eV PV cell (solid line 1602 and dotted line 1604) and a 1.42 eV PV cell (solid line 1605) or a 1.3 eV PV cell (dotted line 1606), together with an overall efficiency (solid line 1608 and dotted line 1609), all as a function of different PL absorber temperatures.

FIG. 16B shows modeled device efficiency under excitation of 500 suns through a 3 cm-long CrNdYb:YAG sample: output efficiency of a 1.1 eV PV cell (line 1611), a 1.42 eV PV cell (line 1612) and the sum of both (line 1613), as a function of PL absorber temperature.

FIG. 16C shows an expected overall heat load falling on a dual-junction PV cell with 1.1 eV and 1.42 eV band-gaps (including thermalization and series resistance losses) as a function of PL absorber temperature, for: direct illumination (dotted line 1615), CrNdYb:YAG (solid line 1616), CrCeNd:YAG (solid line 1617) and CrNdYb:YAG illuminating a 1.1 eV and 1.3 eV band-gap dual-junction cell (dotted line 1618).

In FIG. 16A, for excitation of a dual-junction PV cell with band-gaps of 1.1 eV and 1.42 eV by CrNdYb:YAG emission, it is shown how a total PV efficiency varies from 35% to 38% as the absorber temperature rises to 500° C. (line 1608), following the EQE trend for this sample. A similar chart for a dual-junction PV cell, where the temperature variable is the PV temperature, is overlaid (dotted line 1609). Under direct illumination, the solar cell is 45% efficient at room temperature, benefiting from the high photon current (little or no absorber EQE losses) and maximal utilization of the high band-gap PV. The efficiency, however, drops at elevated temperatures, reaching LSP PV efficiency at 250° C.

Considering a device design of multi-junction PV cells having only two terminals, current matching of the different PV junctions is optionally considered. PV band-gap selection is optionally used to optimize this aspect, and for CrNdYb:YAG, choosing the band-gap pair of 1.1 eV and 1.3 eV leads to similar currents running through the cells at a cost of approximately 1% efficiency drop (dotted line 1609 in FIG. 16A). CrCeNd:YAG is characterized by lower conversion efficiencies of 32% and monotonic reduction with temperature (FIG. 16B), but with convenient current matching with the natural band-gap pair of 1.1 eV and 1.42 eV. Again, comparing these to the theoretical efficiency of a directly illuminated dual-junction cell, we see an efficiency reduction with temperature, crossing LSP PV efficiency at 350° C.

The heat load in FIG. 16C accounts only for thermalization of energetic photons to the PV band-gap, together with additional series resistance heat generated in the cell. The latter is found by calculating an energy difference between an open circuit voltage and an operating voltage (at the maximal power point of the I-V curve). Of the total impinging sun power, 28% of this power would contribute to heat if directly illuminating a room temperature dual-junction PV cell (having 1.1 eV and 1.42 eV band-gaps). If not cooled, the reduction in cell efficiency is followed by additional heating, up to 40% at 400° C. In LSP, for altered sunlight through CrNdYb:YAG or CrCeNd:YAG, only 12% or 9% of the sunlight is converted into heat at the PV, respectively, a value hardly influenced by the absorber temperature.

A calculated dissipated heat indicates a 2.2-2.8 improvement factor using a PL absorber compared to directly illuminating the PV cells. In some embodiments the improvement factor is optionally improved further by accounting for and shielding from IR radiation. A tailored spectral filter ensuring retention of IR radiation, IR radiation emitted from the sample and/or IT radiation transmitted from the sun, in the absorber material will increase the heat load on the absorber while potentially not affecting the PV cells. In such embodiments, simple filtering is optionally used, such as using a layer of ITO.

Additional photonic management issues used in design of an embodiment as described herein include one or more of minimizing PL emission directed back toward the sun; maximizing photon coupling to the PV cells; and optimizing the PV cells' anti-reflective coating for the incident spectrum.

Results for device efficiency and reduction of dissipated heat for the PL materials studied here are very encouraging.

The example embodiment of the ceramic YAG model offers versatility regarding dopant concentration and even gradient doping. A relative low EQE of 56% for ceramic YAG was measured (see the Supplementary Information section), however, this is not inherent to this material type and can potentially be raised.

As many physical processes are involved (e.g., PL, energy transfer, quantum cutting and quenching) changing substrates, dopants and their concentrations, and manufacturing techniques potentially alter the results.

Taking a broader view of LSP, we calculate practical efficiencies compared to those of current state of the art CSP systems, side by side a conventional PV field, and highlight the relative improvement of LCOE (levelized cost of electricity). CSP plant performance is typically governed by three key factors. i. Collector efficiency (η_{C,Rec}), denoting a total power absorbed in the receiver head relative to solar power impinging on the entire collector field. ii. Receiver efficiency (η_{Rec}), which is a ratio of heat transferred to steam from the absorbed heat. iii. Gross-cycle efficiency (η_{G}), representing an operational efficiency of turbine generators (typically Rankine cycle steam turbines). A high turbine efficiency depends strongly on the temperature of the HTF (heat transfer fluid), currently reaching about 560° C. (for tower CSP plants), aiming to exceed 650° C. Taking common tower CSP plants as an example, we refer to an expected overall efficiency of roughly 22%, as the product of the values η_{C}=0.65, η_{Rec}=0.82, and η_{G}=0.416.

An LSP plant introduces other factors into this calculation: iv. An EQE of the PL absorber. v. The ratio of PL average photon energy to absorbed average photon energy, [symbol] ℏω_{PL} [symbol] / [symbol] ℏω_{absorbed} [symbol] . vi. The coupling efficiency of the PL emission to the PV cell, η_{C,PL}. Multiplying these three values provides a single PL efficiency coefficient, η_{PL}=EQE·η_{C,PL}· [symbol] ℏω_{PL} [symbol] / [symbol] ℏω_{absorbed} [symbol] . vii. The material absorptance in wavelengths accessible for PL emission, a_{PL}. viii. Additional infra-red absorptance contributing to heat, a_{IR}. ix. The coupling efficiency of directly transmitted sunlight to the PV cell, η_{C,direct}. x. The PV conversion efficiency of the impinging spectrum, η_{PV}. Note that the transmittance, which directly reaches the PV, is t_{direct}=1−a_{PL}−a_{IR}.

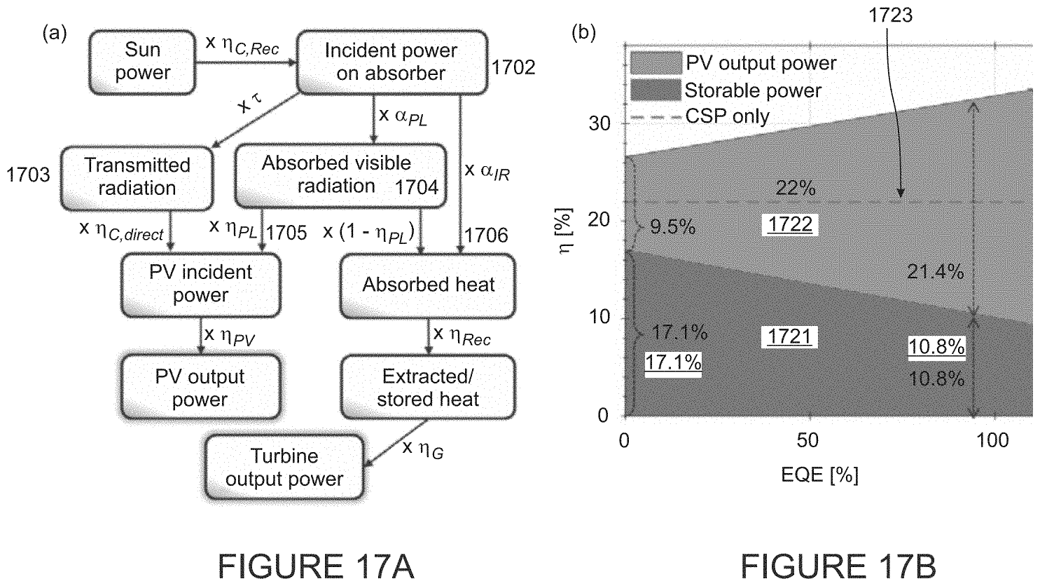

Reference is now made to FIGS. 17A and 17B which are a flowchart and a graph showing overall performance estimation of an example embodiment of the invention.

FIG. 17A shows a flow chart of power flow and a performance coefficient factor for each energy conversion stage.

FIG. 17B shows expected thermal power efficiency (first area 1721) and PV power efficiency (second area 1722) for a plant with variable PL EQE values and with performance coefficients of: η_{C,Rec}=0.65, η_{Rec}=0.82, η_{G}=0.416, η_{PV}=0.65, a_{PL}=0.6, a_{IR}=0.17, η_{C,PL}=0.8, η_{C,direct}=0.98 and [symbol] ℏω_{PL} [symbol] / [symbol] ℏω_{absorbed} [symbol] of 0.65. This is compared to conventional state-of-the-art tower CSP efficiency (dashed line 1723).

A device's total energy output in an example embodiment is depicted in FIG. 17A. Incoming radiation 1702 is divided into a transmitted portion 1703, directly converted at the PV, and absorbed portions 1704. The absorbed portions are divided to a PL portion 1705 coupled to the PV and a thermal portion 1706 directed to the thermal cycle. This is formulated by:

E_{LSP}=PV power ratio+Thermal power ratio=E_{Sun}·η_{C}·{[t_{direct}·η_{C,direct}+a_{PL}·η_{PL}]·η_{PV}+[a_{IR}+a_{PL}·(1−η_{PL})]·η_{Rec}·η_{G}}.

The above formulation is used to show an effect of EQE on device performance, using typical values for each performance coefficient. [symbol] ℏω_{PL} [symbol] / [symbol] ℏω_{absorbed} [symbol] is optionally taken to be 0.65, according to the model used in the Results section, aim is taken to be 0.6 and a_{IR} to be 0.17 (taking full absorption above 1100 nm), resulting in a sunlight transmittance, t_{direct}, of 0.23.

A calculated PL coupling efficiency, η_{C,PL} is 0.8 based on a ray-tracing calculation, and transmitted sunlight is coupled according to a η_{C,direct} of 0.98. Using known spectral response curves for state-of-the-art PV cells, in the wavelength range of the PL emission, and calculated thermal and radiative losses, we reach a practical PV efficiency, η_{PV}, of about 0.65. The resulting overall conversion efficiency is approximately 26.6% of incoming sun power when EQE=0, of which approximately 17.1% is converted by thermal (storable) energy. This relative reduction in CSP efficiency, compared to the 22% stated earlier (shown in FIG. 17B dashed line 1723), depicts accessible power that goes to the turbine while its internal efficiency is unchanged. For higher EQE, the PV efficiency portion increases as well, while the thermal portion is reduced. For an EQE of 90%, the PV reaches an efficiency of approximately 21.4% and the thermal power is reduced to approximately 10.8%, producing an overall approximately 32.2% solar conversion efficiency.

In some embodiments an option for dynamic control of transmitted power toward the PV cells potentially enables a flexibility which is sometimes desired for load-following power plants, specifically when dealing with intermittent solar power and a fluctuating demand curve. For plentiful sunshine periods, a high electricity demand is answered by operating the LSP plant at its full potential. When demand is low, introducing a fully absorbing element (say, by pulling down a black baffle) allows for more power to be directed to the thermal cycle for storage.

In some embodiments LSP offers an option of limited sunlight conversion under weather considered poor for CSP (such as, by way of some non-limiting examples, partial clouds and haziness), where a PL absorber can transmit toward the PV cells even when it is too cold to harvest heat by HTF. Such an operational mode potentially does not perform as well as a conventional PV field however such a possibility greatly increases a capacity factor of LSP compared to CSP.

An LSP 1.5-factor improvement in overall efficiency compared to 22% of CSP suggests a similar drop in LCOE (levelized cost of electricity). Using a value of 6 ¢/kWh LCOE for CSP and 2 ¢/kWh for a utility-scale PV field, a side-by-side PV-CSP plant with similar production capacity for each has an overall LCOE of 4Ø/kWh. A comparable LSP plant with similar storage capacity as the CSP plant, land usage similar to the joint PV-CSP plant, and 10% additional investment costs in PL absorbers and PV cells, has an LCOE of approximately 2.7 ¢/kWh (see the Supplementary Information section). For a case where PV LCOE is higher than 2 ¢/kWh, the relative reduction in LCOE improves. For example, at PV LCOE of 4 ¢/kWh LSP offers an approximately 50% improvement.

The LSP concept, in various embodiments thereof, is a viable and potentially cost effective solar conversion technology, enabling potential cost reduction to below 3 ¢/kWh.

In some LSP embodiments, in contrast to CPV/T technologies, a heat load on the PV cells is reduced, while utilizing heat as in conventional CSP plants.

Example materials with a tailored absorption and PL at high EQE and at relevant temperatures for CSP are mentioned herein.

Supplementary Information

Material Characterization

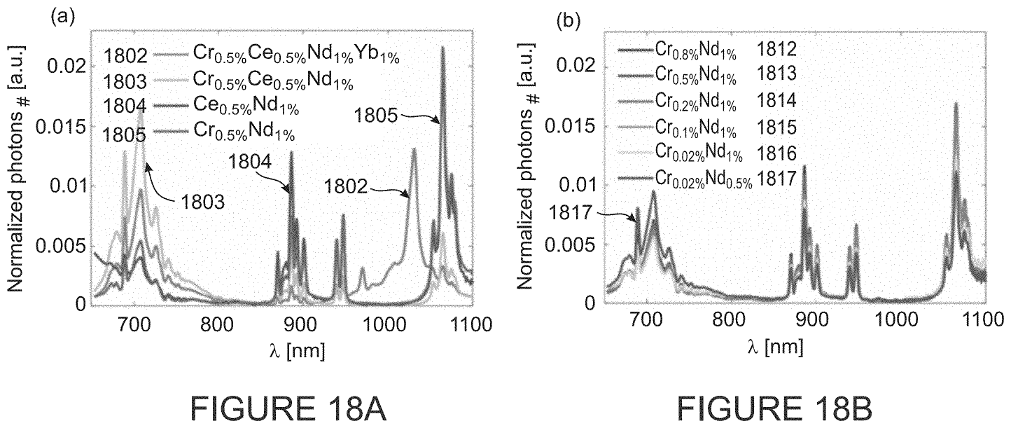

Room temperature EQE for a variety of samples examined are presented in Table 1 below, including dopant concentration and a manufacturer's name. Ceramic samples marked as produced in lab were fabricated by spark plasma sintering of doped YAG powders synthesized by co-precipitation. Emission spectra for selected samples are presented in FIGS. 18A and 18B.

TABLE 1
List of YAG single crystals and ceramics, dopant concentration,
manufacturer and measured EQE. Some non-limiting
example samples chosen for deeper examination are
highlighted in rows 2 and 4 of Table 1.

| | | Dopant concentration [wt %] | | | | | EQE |
|---|---|---|---|---|---|---|---|
| No. | Type | Cr³⁺ | Ce³⁺ | Nd³⁺ | Yb³⁺ | Manufacturer | [%] |
| 1 | Single | 0.5 | 0 | 1 | 0 | Baikowski | 62 |
| | crystal | | | | | Japan | |
| 2 | Single | 0.5 | 0.5 | 1 | 0 | SIOM* | 79 |
| | crystal | | | | | | |
| 3 | Single | 0.5 | 0.5 | 1 | 1 | SIOM* | 66 |
| | crystal | | | | | | |
| 4 | Single | 0.5 | 0 | 1 | 1 | SIOM* | 84 |
| | crystal | | | | | | |
| 5 | Ceramic | 0.02 | 0 | 0.5 | 0 | In lab | 20 |
| 6 | Ceramic | 0.02 | 0 | 1 | 0 | In lab | 9 |
| 7 | Ceramic | 0.1 | 0 | 1 | 0 | In lab | 20 |
| 8 | Ceramic | 0.2 | 0 | 1 | 0 | In lab | 18 |
| 9 | Ceramic | 0.5 | 0 | 1 | 0 | In lab | 18 |
| 10 | Ceramic | 0.8 | 0 | 1 | 0 | In lab | 17 |
| 11 | Ceramic | 0.5 | 0.5 | 1 | 1 | In lab | 56 |

*Shanghai Institute of Optics and Fine Mechanics

Reference is now made to FIGS. 18A and 18B, which are graphs of emission spectra of YAG doped at different dopant concentrations according to some example embodiments of the invention.

FIG. 18A shows normalized emission spectra of YAG single crystals doped with different combinations of Cr3+, Ce3+, Nd3+ and Yb3+.

FIG. 18B shows normalized emission spectra of YAG ceramic doped with various concentrations of Cr3+ and Nd3+.

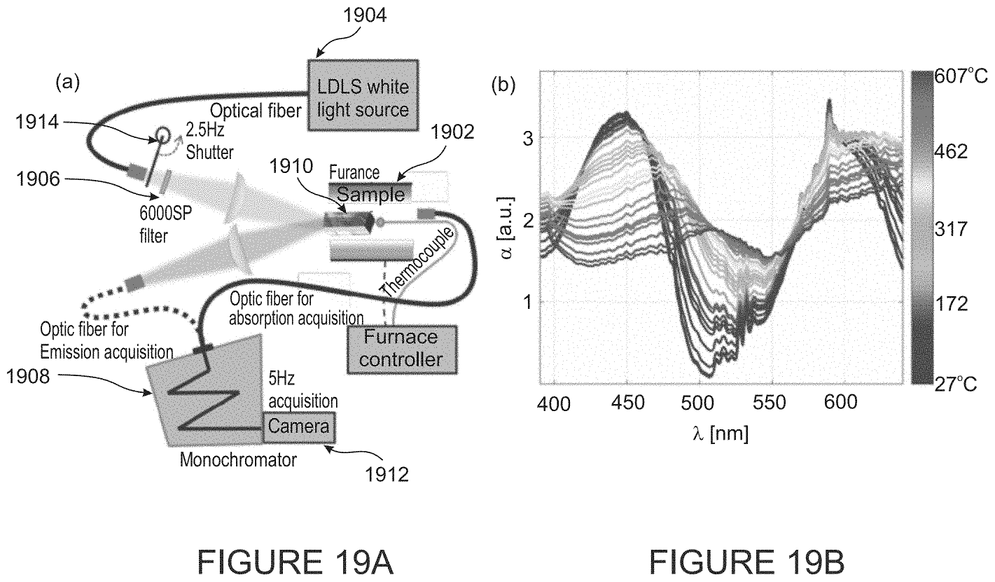

Reference is now made to FIG. 19A, which is a simplified illustration of an experimental setup used for measuring experimental results of example embodiments of the invention.

FIG. 19A shows a temperature controlled micro-furnace 1902 which is intended to heat a sample 1910. Excitation by an LDLS broad white light source 1904, filtered 1906 for short-pass 650 nm wavelengths, and focused onto a front facet of the sample 1910. Collection by a spectrophotometer is placed behind the sample 1910 for absorption measurement, and in front for PL measurement. Also, for PL emission, a real-time background measurement is performed by synchronizing acquisition and a mechanical shutter 1914.

The absorption spectra of CrCeNd:YAG and CrNdYb:YAG (for example as shown in FIGS. 14B and 14C) were measured using a spectrometer (Agilent Cary 5000) in a wavelength range of 300 nm to 1300 nm on a 3 mm-thick sample 1910, and corrected for scattering attenuation. High temperature absorption was measured, as an alternative, by placing a measured sample 1910 inside a temperature controlled micro-furnace (MHI) 1902, while exciting with a broad white light 1904 of 400-650 nm, using a laser driven light source (Energetiq EQ1500 LDLS) filtered by a 650 nm short-pass filter 1906. The excitation is similar to excitation used for emission efficiency measurement, as explained below. The light beam was collimated to pass through the furnace if no sample was placed within. When a sample was positioned inside, transmitted spectrum was measured by a collection system on the other side of the furnace—a fiber leading to a monochromator 1908 (Andor Shamrock 303i) with a Si camera 1912 (Andor iXon). The spectrum was spectrally calibrated by a QTH calibration lamp (Newport) and corrected according to room temperature absorption as measured previously, producing high temperature relative absorption. Results for the temperature dependent absorption of CrNdYb:YAG are presented in FIG. 19B.

Reference is now made to FIG. 19B, which is a graph showing results for temperature dependent absorption of CrNdYb:YAG according to an example embodiment of the invention.

FIG. 19B shows a relative absorption spectra of CrNdYb:YAG at different temperatures (from room temperature, up to 600° C.).

Measuring room temperature EQE (FIG. 14D) was done following the protocol described by Mello et al in an article named “An improved experimental determination of external photoluminescence quantum efficiency” by de Mello, J. C., Wittmann, H. F. & Friend, R. H. in Adv. Mater. 9, 230-232 (1997). Each sample was placed in an integration sphere (LabSphere 4″) and excited by the LDLS white light in the 400-650 nm range. The measured emission in the range of 670 nm to 1300 nm was collected to the monochromator (Andor Shamrock i303) with both the Si and GaAs (Andor iXon iDus) cameras. The entire setup is calibrated against a standard calibration lamp (Newport). The measuring procedure of in-line excitation, out-of-line excitation and reference measuring, was repeated 12 times per sample, with less than 4% standard deviation for each sample.

Emissions at elevated temperatures were measured using the same excitation source (400-650 nm LDLS) while the sample was placed inside the micro-furnace (FIG. 19A). The emission was then collected by the same spectrophotometer system (Andor Shamrock i303 with iXon and iDus cameras). At room temperature, emission were compared to the previously measured EQE and calibrated accordingly. To correct for instability of the background thermal radiation of the furnace, modulation of the excitation source was performed at half the frequency of the acquisition rate: 2.5 Hz mechanical shutter modulation, and 5 Hz acquisition—which is much slower than the fluorescent lifetime. The procedure provided sequential measurement of background and signal. The resulting measured emissions were optionally corrected according to the temperature dependent absorption (for the excitation wavelength range), providing an accurate ratio of emission to absorption, eventually providing the temperature dependent EQE (FIG. 14D). Note that the background correction subtracted any thermal emission emanating from the PL material itself, and at very high temperatures, this deviation from the real emission (PL+thermal) becomes substantial. In some embodiments the drastic reduction in EQE above 600° C. is followed by complementary thermal emission.

Sunlight Excitation

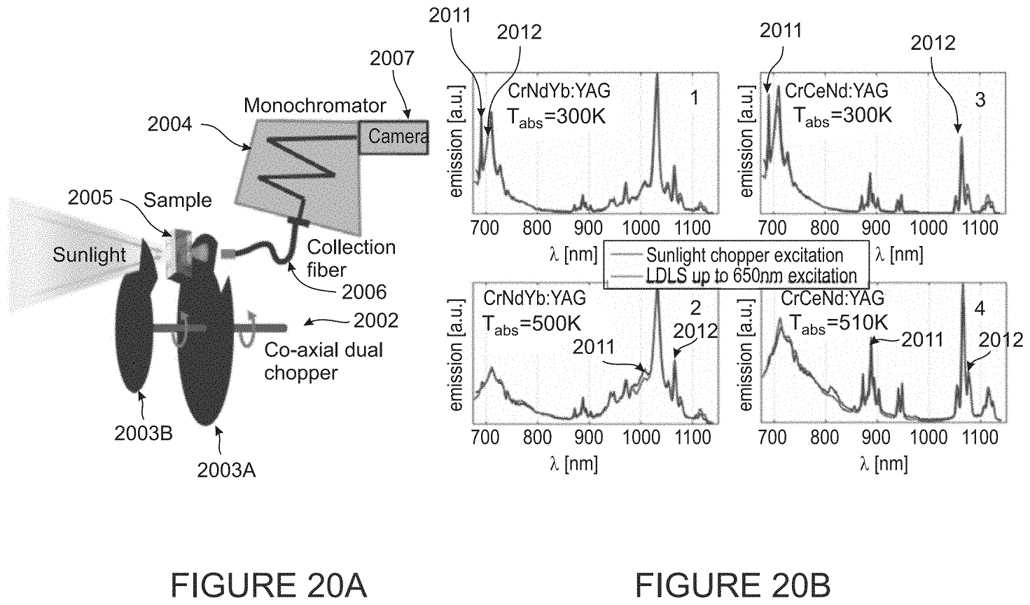

Reference is now made to FIG. 20A, which is a simplified illustration of an experimental setup used for measuring experimental results of example embodiments of the invention.

FIG. 20A shows an experimental setup for measuring PL spectra emitted from a sample, while excited by a broad solar radiation. A dual axis chopper 2002 (produced in lab) rotated at 20 k RPM. During each cycle, the excitation was blocked from registering in a spectrophotometer 2004, while long lifetime PL emission passed through to a collection fiber 2006.

Reference is now additionally made to FIG. 20B, which shows four graphs with results PL emission results measured by excitation by broad sunlight excitation and LDLS white light according to example embodiments of the invention.

FIG. 20B shows PL emission results of CrNdYb:YAG (graphs marked 1 and 2) and CrCeNd:YAG (graphs marked 3 and 4) at 300K (graphs 1 and 3) and 500 K (graphs 2 and 4), each measured by excitation by broad sunlight excitation of the entire spectrum (lines 2011) and LDLS white light source up to 650 nm (orange lines 2012).

To compare LDLS partial white light excitation (400-650 nm) to excitation by a full sunlight spectrum, an experimental setup was built to measure the broadband PL emission when excited by sunlight. An in-lab solar collector system coupled sunlight to an optical fiber and this was focused onto the PL absorber (FIG. 20A). To solve an issue of overlapping between excitation and emission wavelengths, two synchronized and out-of-phase chopper wheels 2003A 2003B were placed before and after the sample 2005. This allows measuring the PL's emission spectra as the collector side wheel 2003A opens, when the sunlight is blocked by the excitation-side wheel 2003B—and vice-versa. Collection of the PL was done by the monochromator and a GaAs camera 2007.

In some embodiments calculating a synchronizing acquisition rate with the chopper wheels is optionally not required. A lifetime of the rare earth (RE) emitters is in the order of milliseconds; and the chopping frequency is selected to be in the order of kHz. A CO₂ laser was optionally used to heat the sample and the temperature was measured by spectrum fitting to PL emission spectrum measured in the furnace. The resulting sunlight-excited PL was compared to a PL emission under 400-650 nm excitation to yield an overall similar shape (see graphs in FIG. 20B), leading to a conclusion that LDLS excitation is an adequate solar simulator for these materials regarding PL emission.

Altered spectra were measured, caused by transmitted sunlight and PL emission through the two samples examined in this work (FIG. 15A-D). This was done by a sunlight beam (also using the in-lab solar collector system) transmitted through the samples that were placed inside an integration sphere (LabSphere) and measuring the resulting emission spectra.

An Example Model

Two output factors are now described: the power conversion efficiency of the device, η, and the total dissipated heat on the PV cells. An algorithm, using MATLAB code, calculated these values as a function of one or more of the following factors:

PV cell type;

PV cell size;

PV cell spectral response;

solar spectrum;

solar concentration ratio;

absorber dimensions;

absorber absorption;

absorber emission spectra;

absorber EQE; and

additional cavity properties such as dimension and spectral reflectivity of various surfaces.

The direct solar spectrum of AM1.5 was taken from NREL, and multiplied by the concentration ratio. Previously measured absorption and emission data for each sample, CrCeNd:YAG and CrNdYb:YAG, was used to estimate the response of each material to sunlight excitation. Temperature dependent absorption spectra (FIG. 19B) were used to find total absorbed solar photons using Lambert's law. The dimensions of the absorber were chosen to allow substantial sunlight absorption (4 cm long for CrNdYb:YAG and 3 cm for CrCeNd:YAG). The temperature dependent emission, according to furnace measured spectra (FIGS. 14B and 14C), were normalized by the number of absorbed solar photons to produce the total PL emission. Ultimately, the calculation estimate the response where each PV cell was exposed to the absorber PL emission, together with the transmitted sunlight not absorbed in the sample (FIGS. 15C and 15D).

An ideal dual-junction PV cell, having a step-function spectral response up to the band-edge for each junction separately, was optionally selected for the model. Each junction in the model was constructed to accept only photons in the relevant wavelength range, i.e., all photons up to the band-edge for the high band-gap junction and photons between band-edges for the low band-gap junction. Calculating the efficiency of each was performed by detailed balance, individually calculating the working voltage and current of each junction (four-terminal configuration).

It is noted that in an ideal cell detailed balance calculation, absorption of a photon is followed either by a radiative recombination or by an electron-hole extraction.

Dissipated heat in the PV cell was calculated by each photon thermalization process (the difference between the photon energy and the junction band-edge), together with the energy difference between the operating voltage (at the maximal power point of the current-voltage curve) and the open circuit voltage of the junction. The latter is attributed to the junction's series resistance or the Carnot. These are the only contributors taken to heat, as an example choice for the case of ideal cells. For non-ideal cells, as is considered in the LCOE calculations below, additional one or more factors may have contribution to heating, for example: a parasitic below band-gap absorption, Boltzmann losses and emission losses.

Levelized Cost of Electricity (LCOE) Estimation.

Two utility scale solar plants are now compared: a first solar plant is a joint PV field and CSP plant, which is considered a benchmark standard solution and a second solar plant is a LSP plant. To compare the two solar plants are planned to supply a same overall PV and thermal (storable) production capacity.

For a PL absorber with EQE of 90%. storable power in LSP is roughly half that of a conventional CSP plant (Ratio of first area 1721 at 90% EQE and value of 22% of dashed line 1723 of FIG. 17B). Accordingly, a LSP plant with a double solar field area than an area of a CSP plant will provide the same accessible power for the thermal (storable) capacity. According to FIG. 17B the same LSP planet will produce 3 time electricity (ratio between second area 1722 and first area 1721 lines for 90% EQE). In order to compare the same output scenario, we therefore choose, for this case, the PV field placed beside the CSP plant to occupy 3 times the CSP capacity. For such capacities provided by the CSP along a PV plant, the LCOE of both would be the mean value of each of their LCOE's normalized by their capacities. For the case of the values of 6 ¢/kWh and 2 ¢/kWh respectively, the expected LCOE of the joint CSP-PV plant is (1×6 ¢/kWh+3×2 ¢/kWh)/4=3 ¢/kWh.

In tower CSP plants a mirror field embodies approximately 25% of its LCOE, that is 1.5 ¢/kWh. When calculating LCOE of LSP plants we also estimate a 10% cost increase led by introduction of the PL absorber and PV cells in the receiver head. Such estimation is justified due to the solar concentration, conventionally between 500 and 1000 suns, which reduces overall costs of components at the focal point. Taking these factors into consideration a mean LCOE for LSP plant results in (1×6.6 ¢/kWh+1×1.5 ¢/kWh)/4=2 ¢/kWh. For the PV's LCOE of 4 ¢/kWh, which is suitable for North America and Europe, a similar calculation will result in 4.5 ¢/kWh for the CSP-PV scenario compared to the SPL mean LCOE of 2 ¢/kWh. That is more than a 50% LCOE reduction.

It is expected that during the life of a patent maturing from this application many relevant photoluminescent (PL) materials will be developed and the scope of the term PL material is intended to include all such new technologies a priori.

It is expected that during the life of a patent maturing from this application many relevant photovoltaic (PV) materials will be developed and the scope of the term PV material is intended to include all such new technologies a priori.

It is expected that during the life of a patent maturing from this application many relevant photovoltaic (PV) cells will be developed and the scope of the term PV cell is intended to include all such new technologies a priori.

The terms “comprising”, “including”, “having” and their conjugates mean “including but not limited to”.

The term “consisting of” is intended to mean “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a unit” or “at least one unit” may include a plurality of units, including combinations thereof.

The words “example” and “exemplary” are used herein to mean “serving as an example, instance or illustration”. Any embodiment described as an “example or “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

As used herein the terms “about” and “approximately” refer to ±20%.

Unless otherwise indicated, numbers used herein and any number ranges based thereon are approximations within the accuracy of reasonable measurement and rounding errors as understood by persons skilled in the art

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub combination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

To the extent that section headings are used, they should not be construed as necessarily limiting.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1. A system for energy conversion comprising:
photoluminescent (PL) material for absorbing solar radiation and emitting PL radiation;
a solar concentrator for concentrating solar radiation on the PL material to heat the PL material to a temperature above 150 degrees Celsius;
photovoltaic (PV) material configured to absorb the PL radiation; and
a chamber for containing the PL material and Heat Transfer Fluid (HTF),
and further comprising the system configured to pipe the HTF from the chamber to a heat engine for conversion of HTF heat to energy.

2. The system of claim 1 comprised in a solar energy harvesting system.

3-5. (canceled)

6. The system of claim 1, wherein the chamber comprises walls are transmissive at wavelengths corresponding to a bandgap of the PV material.

7. The system of claim 1, wherein the PL material is configured to emit PL radiation comprising at least enough energy to be absorbed by the PV material and cause the PV material to generate electricity.

8-10. (canceled)

11. A method for energy conversion comprising:
placing photoluminescent (PL) material in concentrated solar radiation, thereby causing the PL material to absorb solar radiation, to heat the PL material to a temperature above 150 degrees Celsius and to emit PL radiation;
placing photovoltaic (PV) material in the PL radiation to produce electricity;
heating Heat Transfer Fluid (HTF) by placing near the heated PL material; and
piping the heated HTF to a heat engine for conversion of HTF heat to energy.

12. The method of claim 11 wherein the system for conversion of HTF heat to energy comprises a system for converting to electricity.

13. The method of claim 11 wherein the system for conversion of HTF heat to energy comprises a system for converting to chemical energy.

14-17. (canceled)

18. The system of claim 1 wherein said PV material is comprised in:
a first photovoltaic (PV) cell comprising a first higher bandgap PV material to absorb radiation emitted by the PL material at a first PL emission wavelength peak; and
a second PV cell comprising a second lower bandgap PV material to absorb radiation emitted by the PL material at a second PL emission wavelength peak.

19-22. (canceled)

23. The system of claim 1, and further comprising a wavelength selective radiation scatterer comprised within the PL material.

24-25. (canceled)

26. The system of claim 1, wherein said heat engine comprises a turbine for generating electricity from heat absorbed by the PL material.

27-29. (canceled)

30. The system of claim 18, wherein the lower bandgap PV material and higher bandgap PV material are selected from a group consisting of: Si, GaAs, c-Si, InP, InGaP, GaInNAs, mc-Si, CdTe, AlGaAs, GaSb, Ge, a-Si, Cu2S, CIGS, GaP, GaN, PbO, Perovskites.

31. The system of claim 18, wherein the higher bandgap PV material is selected from a group consisting of: GaAs, GaInP, InP, CdTe, a-Si, AlGaAs, GaInAs, GaInAsP, AlGaInP, InGaAs, InGaP, CdS GaP, GaN, PbO, CdSe, PbI2 Cu2O, ZnTe, MAPI, ZnO, SiC, GaAsP.

32-33. (canceled)

34. The system of claim 18, wherein the higher bandgap PV material and the lower bandgap PV material are located in a cavity designed to capture the PL emission.

35. The system of claim 34, and further comprising a wavelength-selective reflective filter located at an entrance of the cavity, wherein the selective reflectivity matches a wavelength of peak emission of the PL material.

36-41. (canceled)

42. The system of claim 1, wherein said PL material comprises a PL material with an absorption spectrum between 1 micron and 1.5 microns for absorbing radiation from the sun, and transferring heat to said HTF.

43. The system of claim 42 in which the material with an absorption spectrum between 1 micron and 1.5 microns comprises a layer of Indium Tin Oxide (ITO).

44. (canceled)

45. A method for producing electric energy comprising:
heating a photoluminescent (PL) material;
exposing the PL material to incident radiation, thereby causing the PL material to emit radiation at a plurality of PL emission wavelength peaks; and
using at least one photovoltaic (PV) cell to absorb radiation emitted by the PL material and produce electric energy.

46. The method of claim 45, wherein the PV cell has at least two PV absorption band-gaps to absorb radiation emitted by the PL material using at least two of the PL emission wavelength peaks.

47. The method of claim 45, wherein the heating is by absorption of the incident radiation.

48. The method of claim 45, wherein the heating the PL material comprises heating to a temperature above 100 degrees Celsius.

49. The method of claim 45, wherein the heating the PL material comprises heating to a temperature above 500 degrees Celsius.

50. The method of claim 45, and further comprising using a heat engine to generate electricity from heat absorbed by the PL material.
